(19) United States
(12) Patent Application Publication
(10) Pub. No.: US 2014/0051242 A1
(43) Pub. Date: Feb. 20, 2014

(54) Conductive Metallic and Semiconductor Ink Composition

(71) Applicants: Vera Nicholaevna Lockett, Phoenix, AZ (US); Mark David Lowenthal, Gilbert, AZ (US); Neil O. Shotton, Tempe, AZ (US); William Johnstone Ray, Fountain Hills, AZ (US); Tricia Youngbull, Tempe, CA (US); Theodore I. Kamins, Palo Alto, CA (US)

(72) Inventors: Vera Nicholaevna Lockett, Phoenix, AZ (US); Mark David Lowenthal, Gilbert, AZ (US); Neil O. Shotton, Tempe, AZ (US); William Johnstone Ray, Fountain Hills, AZ (US); Tricia Youngbull, Tempe, CA (US); Theodore I. Kamins, Palo Alto, CA (US)

(73) Assignee: NthDegree Technologies Worldwide Inc., Tempe, AZ (US)

(21) Appl. No.: 13/587,380

(22) Filed: Aug. 16, 2012

(51) Int. Cl. C09D 11/00; H01L 21/288

(52) U.S. Cl. CPC C09D 11/52; H01L 21/288
USPC 438/610; 252/512; 252/513; 252/514; 252/503

(57) ABSTRACT

A representative printable composition comprises a liquid or gel suspension of a plurality of metallic particles; a plurality of semiconductor particles; and a first solvent. The pluralities of particles may also be comprised of an alloy of a metal and a semiconductor. The composition may further comprise a second solvent different from the first solvent. In a representative embodiment, the first solvent comprises a polyol or mixtures thereof, such as glycerin, and the second solvent comprises a carboxylic or dicarboxylic acid or mixtures thereof, such as glutaric acid. In various embodiments, the metallic particles and the semiconductor particles are nanoparticles between about 5 nm to about 1.5 microns in any dimension. A representative metallic and semiconductor particle ink can be printed and annealed to produce a conductor.

### FIELD OF THE INVENTION

The present invention in general is related to compositions for conductive inks and polymers utilized to produce a conductor, deposition methods and resulting apparatuses.

### BACKGROUND OF THE INVENTION

Many conductive inks include a particulate metal, such as silver or aluminum, in a binder or binding medium. While such inks produce conductors (when cured) which are substantially conductive and have a comparatively low electrical impedance (or resistance), when such inks are to be utilized for bonding to other, second conductors, the curing temperatures for such conductive inks may exceed the melting temperature of such second conductors and cannot be utilized. In addition, such conductive inks may not be suitable for forming ohmic contacts directly with a semiconductor substrate such as silicon. Instead, such conductive inks are typically utilized to form circuit board traces for coupling to metal contacts created as part of integrated circuit packaging, with any ohmic contacts with a semiconductor substrate having been previously formed at a foundry under clean room conditions, such as through vapor deposition or sputtering of a metal, as a semiconductor wafer is fabricated into a plurality of discrete integrated circuits.

Such fabrication techniques for forming ohmic contacts to a semiconductor substrate do not scale well for devices larger than a semiconductor wafer. In addition, depending upon the processing techniques, some of the semiconductor substrate may be lost or deformed, which may be significant when trying to preserve a specific shape, such as substantially spherical, of the semiconductor substrate.

Accordingly, a need remains for a conductive ink, polymer or composition which may be printed and, when annealed, alloyed or otherwise cured, produces a resulting conductor which is stable, fixed in place, and capable of providing electrical connections to other, second conductors at temperatures below a melting point of such second conductors. Various methods and compositions are also needed to create direct ohmic contacts to semiconductor substrates and bonding to other conductors, and further provide a comparatively low electrical impedance (or resistance). In addition, a need remains for such a composition to be capable of annealing or curing into a stable conductor at comparatively lower processing temperatures, and be suitable for a wide variety of applications, such as for use in lighting and photovoltaic panels.

### SUMMARY

Representative embodiments provide a “metallic and semiconductor nanoparticle ink” and a “metallic nanoparticle ink”, namely, a liquid or gel suspension of metallic nanoparticles or metallic nanoparticles with semiconductor nanoparticles (and also metallic microparticles and/or semiconductor microparticles in selected embodiments), which is capable of being printed, such as through screen printing or flexographic printing, for example and without limitation, to produce a substantially stable conductor when annealed.

A representative composition comprises: a plurality of metallic nanoparticles; a plurality of semiconductor nanoparticles; and a first solvent.

In a representative embodiment, the plurality of metallic nanoparticles have a size in any dimension between about 5 nm and about 1.0μ; the plurality of semiconductor nanoparticles have a size in any dimension between about 5 nm and about 1.5μ. In another representative embodiment, the plurality of metallic nanoparticles have a size in any dimension between about 5 nm and about 200 nm and the plurality of semiconductor nanoparticles have sizes in any dimension between about 5 nm and about 200 nm. In another representative embodiment, the composition further comprises a plurality of metallic microparticles having sizes in any dimension between about 1μ, and about 20μ, and may also further comprise a plurality of semiconductor microparticles having sizes in any dimension between about 1μ, and about 20μ.

In a representative embodiment, each nanoparticle of the plurality of metallic nanoparticles and of the plurality of semiconductor nanoparticles comprises an alloy of a metal and a semiconductor.

In another representative embodiment, each semiconductor nanoparticle of the plurality of semiconductor nanoparticles further comprises a doped semiconductor. For example, each semiconductor nanoparticle of the plurality of semiconductor nanoparticles may further comprises a dopant selected from the group consisting of: boron, arsenic, phosphorus, gallium, and mixtures thereof.

In a representative embodiment, the plurality of metallic nanoparticles comprises at least one metal selected from the group consisting of: aluminum, copper, silver, gold, nickel, palladium, tin, platinum, lead, zinc, bismuth, alloys thereof, and mixtures thereof.

Also in a representative embodiment, the plurality of semiconductor nanoparticles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof. More generally, in a representative embodiment, the plurality of semiconductor nanoparticles comprises at least one semiconductor selected from the group consisting of: silicon, germanium, and mixtures thereof; titanium dioxide, silicon dioxide, zinc oxide, indium-tin oxide, antimony-tin oxide, and mixtures thereof; II-VI semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof; III-V semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof; and group IV semiconductors including hydrogen terminated silicon, carbon, germanium, and alpha-tin, and combinations thereof.

In a representative embodiment, at least some nanoparticles of the plurality of metallic nanoparticles are passivated. For example, in a representative embodiment, at least some nanoparticles of the plurality of metallic nanoparticles are passivated with at least a partial coating selected from the group consisting of: benzotriazole, zinc phosphate, zinc dithiophosphate, tannic acid, hexafluoroacetylacetone, and mixtures thereof.

In another representative embodiment, the composition may further comprise an antioxidant. For example, in a representative embodiment, the composition may further comprise an antioxidant selected from the group consisting of: N,N-diethylhydroxylamine, ascorbic acid, hydrazine, hexamine, phenylenediamine, and mixtures thereof.

In a representative embodiment, the first solvent comprises at least one solvent selected from the group consisting of: water; alcohols such as methanol, ethanol, N-propanol (including 1-propanol, 2-propanol (isopropanol or IPA), 1-methoxy-2-propanol), butanol (including 1-butanol, 2-butanol (isobutanol)), pentanol (including 1-pentanol, 2-pentanol, 3-pentanol), hexanol (including 1-hexanol, 2-hexanol, 3-hexanol), octanol, N-octanol (including 1-octanol, 2-octanol, 3-octanol), tetrahydrofurfuryl alcohol (THFA), cyclohexanol, cyclopentanol, terpineol; lactones such as butyl lactone; ethers such as methyl ethyl ether, diethyl ether, ethyl propyl ether, and polyethers; ketones, including diketones and cyclic ketones, such as cyclohexanone, cyclopentanone, cycloheptanone, cyclooctanone, acetone, benzophenone, acetylacetone, acetophenone, cyclopropanone, isophorone, methyl ethyl ketone; esters such ethyl acetate, dimethyl adipate, proplyene glycol monomethyl ether acetate, dimethyl glutarate, dimethyl succinate, glycerin acetate, carboxylates; carbonates such as propylene carbonate; polyols (or liquid polyols), glycerols and other polymeric polyols or glycols such as glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; carboxylic acids, including alkyl carboxylic acids and higher-order carboxylic acids (such as dicarboxylic acids, tricarboxylic acids, etc.), such as formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid; tetramethyl urea, n-methylpyrrolidone, acetonitrile, tetrahydrofuran (THF), dimethyl formamide (DMF), N-methyl formamide (NMF), dimethyl sulfoxide (DMSO); thionyl chloride; sulfuryl chloride; and mixtures thereof acids, including organic acids (in addition to carboxylic acids, dicarboxylic acids, tricarboxylic acids, alkyl carboxylic acids, etc.), such as hydrochloric acid, sulfuric acid, carbonic acid; and bases such as ammonium hydroxide, sodium hydroxide, potassium hydroxide; and mixtures thereof.

In another representative embodiment, the first solvent comprises a polyol or mixtures thereof. For example, in a representative embodiment, the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof.

In another representative embodiment, the first solvent comprises any type of carboxylic acid, namely, any compound with a carboxyl group (i.e., R—COOH, in which “R” is any monovalent organic functional group), including without limitation higher order carboxylic acids such as dicarboxylic acids, tricarboxylic acids, and mixtures thereof. For example, in a representative embodiment, the first solvent comprises a dicarboxylic acid selected from the group consisting of: ethanedioic (oxalic) acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof. Also for example, in a representative embodiment, the first solvent comprises a carboxylic acid selected from the group consisting of: formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In another representative embodiment, the composition may further comprise a second solvent different from the first solvent. For example, in a representative embodiment, the first solvent comprises a polyol or mixtures thereof, and the second solvent comprises a carboxylic or dicarboxylic acid or mixtures thereof. Also for example, in a representative embodiment the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In another representative embodiment, the first solvent comprises a polyol or mixtures thereof, and the second solvent comprises at least one organic acid selected from the group consisting of: carboxylic acids, dicarboxylic acids, tricarboxylic acids, alkyl carboxylic acids, formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In another representative embodiment, the plurality of metallic nanoparticles are comprised of aluminum; the plurality of semiconductor nanoparticles are comprised of silicon; the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; and the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In another representative embodiment, the plurality of metallic nanoparticles are present in an amount of about 3% to 20% by weight; the plurality of semiconductor nanoparticles are present in an amount of about 10% to 50% by weight; the first solvent is present in an amount of about 30% to 60% by weight and comprises a polyol or mixtures thereof; the second solvent is present in an amount of about 10% to 40% by weight and comprises a carboxylic or dicarboxylic acid or mixtures thereof.

In yet another representative embodiment, the plurality of metallic nanoparticles are present in an amount of about 5% to 10% by weight; the plurality of semiconductor nanoparticles are present in an amount of about 20% to 40% by weight; the first solvent is present in an amount of about 40% to 50% by weight and comprises a polyol or mixtures thereof; and the second solvent is present in an amount of about 15% to 25% by weight and comprises a carboxylic or dicarboxylic acid or mixtures thereof.

In another representative embodiment, the plurality of metallic nanoparticles are present in an amount of about 7% to 9% by weight; the plurality of semiconductor nanoparticles are present in an amount of about 27.5% to 32.5% by weight; the first solvent is present in an amount of about 42% to 46% by weight and comprises glycerin; and the second solvent is present in an amount of about 17% to 21% by weight and comprises glutaric acid.

In various representative embodiments, the composition has a viscosity substantially between about 50 cps and about 25,000 cps at about 25° C. In another representative embodiment the composition has a viscosity substantially between about 100 cps and about 10,000 cps at about 25° C.

A method of using the composition is also disclosed, with the method comprising printing and annealing the composition to form an electrical conductor.

In another representative embodiment, a composition comprises: a plurality of metallic nanoparticles; a plurality of semiconductor nanoparticles; a first solvent comprising a polyol or mixtures thereof; and a second solvent comprising a carboxylic or dicarboxylic acid or mixtures thereof.

In another representative embodiment, a composition comprises: a plurality of metallic nanoparticles; a plurality of semiconductor nanoparticles; a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In yet another representative embodiment, a composition comprises: a plurality of metallic particles; a plurality of semiconductor particles, wherein the pluralities of metallic particles and semiconductor particles have sizes in any dimension between about 5 nm and about 20μ; a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In another representative embodiment, a composition comprises: a plurality of metallic particles; a plurality of semiconductor particles, wherein the pluralities of metallic particles and semiconductor particles have sizes in any dimension between about 5 nm and about 1.5μ; a first solvent comprising glycerin; and a second solvent comprising pentanedioic (glutaric) acid; wherein the viscosity of the composition is substantially between about 50 cps to about 25,000 cps at 25° C.

In another representative embodiment, a composition comprises: a plurality of conductive particles; a first solvent comprising a polyol or mixtures thereof; and a second solvent comprising a carboxylic or dicarboxylic acid or mixtures thereof.

In another representative embodiment, a composition comprises: a plurality of metallic particles; a first solvent comprising a polyol or mixtures thereof; and a second solvent comprising a carboxylic or dicarboxylic acid or mixtures thereof.

In yet another representative embodiment, a composition comprises: a plurality of semiconductor particles; a first solvent comprising a polyol or mixtures thereof; and a second solvent comprising a carboxylic or dicarboxylic acid or mixtures thereof.

In another representative embodiment, a composition comprises: a plurality of conductive nanoparticles; a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

In yet another representative embodiment, a composition comprises: a plurality of conductive particles have sizes in any dimension between about 5 nm and about 20μ; a first solvent comprising glycerin; and a second solvent comprising pentanedioic (glutaric) acid; wherein the viscosity of the composition is substantially between about 50 cps to about 25,000 cps at 25° C.

Another representative embodiment discloses a composition comprising: a plurality of substantially spherical semiconductor particles; a first solvent comprising a polyol or mixtures thereof; and a second solvent different from the first solvent, the second solvent comprising a carboxylic or dicarboxylic acid or mixtures thereof.

In another representative embodiment, a composition comprises: a plurality of substantially spherical semiconductor particles; and a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; a second solvent different from the first solvent, the second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof; and a third solvent different from both the first solvent and the second solvent.

In another representative embodiment, a composition comprises: a plurality of substantially spherical semiconductor particles present in an amount of about 55% to 65% by weight, wherein each semiconductor particle of the plurality of substantially spherical semiconductor particles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof; a first solvent present in an amount of about 22% to 28% by weight and comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; a second solvent different from the first solvent, the second solvent present in an amount of about 8% to 14% by weight and comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof; and a third solvent different from both the first solvent and the second solvent, the third solvent present in an amount of about 3% to 7% by weight and comprising at least one solvent selected from the group consisting of: tetramethylurea, butanol, isopropanol, and mixtures thereof.

Numerous other advantages and features of the present invention will become readily apparent from the following detailed description of the invention and the embodiments thereof, from the claims and from the accompanying drawings.

### BRIEF DESCRIPTION OF THE DRAWINGS

The objects, features and advantages of the present invention will be more readily appreciated upon reference to the following disclosure when considered in conjunction with the accompanying drawings, wherein like reference numerals are used to identify identical components in the various views, and wherein reference numerals with alphabetic characters are utilized to identify additional types, instantiations or variations of a selected component embodiment in the various views, in which:

Figure (or “FIG.”) 1 is a perspective view illustrating a representative apparatus embodiment.

Figure (or “FIG.”) 2 is a cross-sectional view illustrating a representative apparatus embodiment.

Figure (or “FIG.”) 3 is a first scanning electron micrograph illustrating a cross-section through a second conductor and a first conductor or conductive layer formed using an exemplary metallic and semiconductor nanoparticle ink composition of a representative embodiment.

Figure (or “FIG.”) 4 is a second scanning electron micrograph illustrating a cross-section through a second conductor and a third conductor or conductive layer formed using an exemplary metallic nanoparticle ink composition of a representative embodiment.

Figure (or “FIG.”) 5 is a third scanning electron micrograph illustrating a cross-section through a first conductor or conductive layer formed using a representative metallic and semiconductor nanoparticle ink composition, a third conductor or conductive layer formed using a representative metallic nanoparticle ink composition, and an embedded silicon sphere from a deposited substantially spherical semiconductor particle ink, of a representative embodiment.

Figure (or “FIG.”) 6 is a fourth scanning electron micrograph illustrating a cross-section through a second conductor and a first conductor or conductive layer formed using a solvent composition that is not a combination of a polyol and a carboxylic or dicarboxylic acid or mixtures thereof.

Figure (or “FIG.”) 7 is a flow diagram illustrating an exemplary method embodiment for apparatus fabrication.

### DETAILED DESCRIPTION OF EXEMPLARY EMBODIMENTS

While the present invention is susceptible of embodiment in many different forms, there are shown in the drawings and will be described herein in detail specific exemplary embodiments thereof, with the understanding that the present disclosure is to be considered as an exemplification of the principles of the invention and is not intended to limit the invention to the specific embodiments illustrated. In this respect, before explaining at least one embodiment consistent with the present invention in detail, it is to be understood that the invention is not limited in its application to the details of construction and to the arrangements of components set forth above and below, illustrated in the drawings, or as described in the examples. Methods and apparatuses consistent with the present invention are capable of other embodiments and of being practiced and carried out in various ways. Also, it is to be understood that the phraseology and terminology employed herein, as well as the abstract included below, are for the purposes of description and should not be regarded as limiting.

Representative embodiments provide a plurality of different conductive ink and other compositions, including the use of a highly novel combination of solvents which provide unexpected and serendipitous results. A first representative embodiment provides a composition comprising a liquid and/or gel suspension of metallic nanoparticles and semiconductor nanoparticles. Another representative embodiment provides a composition comprising a liquid and/or gel suspension of metallic nanoparticles, semiconductor nanoparticles, with additional metallic microparticles and semiconductor microparticles. Any of these various compositions is capable of being printed, and may be referred to equivalently herein as “metallic and semiconductor nanoparticle ink”, it being understood that “metallic and semiconductor nanoparticle ink” means and refers to a liquid and/or gel suspension of metallic nanoparticles and semiconductor nanoparticles, and may also include larger, metallic microparticles and semiconductor microparticles, as discussed in greater detail below.

Another representative embodiment provides a composition comprising a liquid and/or gel suspension of metallic nanoparticles and doped semiconductor nanoparticles, such as n, n+, p or p+ doped semiconductor particles. Another representative embodiment provides a composition comprising a liquid and/or gel suspension of metallic nanoparticles, doped semiconductor nanoparticles, with additional metallic microparticles and doped semiconductor microparticles. Any of these various compositions is also capable of being printed, and may be referred to equivalently herein as “metallic and doped semiconductor nanoparticle ink”, it being understood that “metallic and doped semiconductor nanoparticle ink” means and refers to a liquid and/or gel suspension of metallic nanoparticles and doped semiconductor nanoparticles, and may also include larger, metallic microparticles and doped semiconductor microparticles, as discussed in greater detail below.

Yet another representative embodiment provides a composition comprising a liquid and/or gel suspension of nanoparticles and/or microparticles in which each of the nanoparticles and/or microparticles comprise an alloy of a metal and a semiconductor. Any of these various compositions is also capable of being printed, and may be referred to equivalently herein as “alloyed metallic and semiconductor nanoparticle ink”, it being understood that “alloyed metallic and semiconductor nanoparticle ink” means and refers to a liquid and/or gel suspension of particles comprising an alloy of a metal and a semiconductor, as discussed in greater detail below.

Yet another representative embodiment provides a composition comprising a liquid and/or gel suspension of nanoparticles and/or microparticles, such as metallic and/or semiconductor particles, in a combination of solvents comprising a polyol and a carboxylic acid. Yet another representative embodiment provides a composition comprising a liquid and/or gel suspension of nanoparticles and/or microparticles, such as metallic and/or semiconductor particles, in a combination of solvents comprising a polyol and a dicarboxylic acid. Any of these various compositions is also capable of being printed, and may be referred to equivalently herein as a “conductive polyol carboxylic acid-based ink”, it being understood that “conductive polyol carboxylic acid-based ink” means and refers to a liquid and/or gel suspension of metallic and/or semiconductor particles in a plurality of solvents comprising a polyol and a carboxylic acid (or dicarboxylic acid or tricarboxylic acid or mixtures thereof), as discussed in greater detail below. As mentioned above, any type of carboxylic acid may be utilized within the scope of the disclosure for any of the inks, namely, any compound with a carboxyl group (i.e., R—COOH, in which “R” is any monovalent organic functional group), including without limitation higher order carboxylic acids such as dicarboxylic acids, tricarboxylic acids, etc., and mixtures thereof.

Another representative embodiment provides a composition comprising a liquid and/or gel suspension of metallic nanoparticles and semiconductor nanoparticles, including without limitation any of the printable compositions disclosed herein, in combination with an antioxidant compound. Another representative embodiment provides a composition comprising a liquid and/or gel suspension of passivated metallic nanoparticles and semiconductor nanoparticles, including without limitation any of the printable compositions disclosed herein, in which the metallic nanoparticles have a passivating surface coating which prevents or diminishes oxidation. Any reference herein to any composition or ink should be understood to mean and include any such composition or ink which may also have these additional features.

Another representative embodiment provides a composition comprising a liquid and/or gel suspension of metallic nanoparticles, in which the metallic nanoparticles comprise at least two different metals, such as aluminum particles and tin (or bismuth) particles, or mixtures thereof, such as in a conductive polyol carboxylic acid-based ink.

Yet another representative embodiment provides a composition comprising a liquid and/or gel suspension of semiconductor particles, such as substantially spherical semiconductor particles, in a conductive polyol carboxylic acid-based ink, namely, in a combination of solvents comprising a polyol and a carboxylic acid (and/or a dicarboxylic acid). Any of these various compositions is also capable of being printed, and may be referred to equivalently herein as “substantially spherical semiconductor particle ink”, it being understood that “substantially spherical semiconductor particle ink” means and refers to a liquid and/or gel suspension of substantially spherical semiconductor particles in a plurality of solvents comprising a polyol and a carboxylic or dicarboxylic acid, as discussed in greater detail below.

Any of these various compositions is also capable of being printed, and may be referred to equivalently herein as an “ink”.

Various metallic and semiconductor nanoparticle inks are also capable of being annealed to another, second conductor, such as a thin sheet or foil of aluminum, considerably below the melting temperature of the second conductor. Exemplary conductors, apparatuses and systems formed by printing such exemplary metallic and semiconductor nanoparticle and other inks are also disclosed.

An exemplary method of the invention also comprises depositing various layers of these different conductive inks, for example, to produce a conductor (or conductive) layer which can bind to and create a comparatively low impedance electrical connection (or ohmic contact) to semiconductor particles such as silicon or other semiconductor spheres, and further which can bind to and create a comparatively low impedance electrical connection between another, second conductor and such semiconductors, such as for the manufacture of LED-based devices and photovoltaic devices, for example and without limitation, and as may be utilized in the second related applications discussed below.

The various inks disclosed herein may be deposited, printed or otherwise applied to any substrate, device, or may be deposited, printed or otherwise applied to any product of any kind or to form any product of any kind, including lighting, photovoltaic panels, electronic displays such as computer, television, tablet and mobile device displays, packaging, signage or indicia for product packaging, or as a conductor for any other product or device, such as a consumer product, a personal product, a business product, an industrial product, an architectural product, a building product, etc. The various conductive and/or semiconductor inks may be printed onto a substrate, device, article, or packaging thereof, as either a functional or decorative component of the article, package, or both. In one embodiment, the various inks are printed in the form of indicia and combined with light emitting diodes. In another embodiment, the metallic and semiconductor nanoparticle ink and a metallic ink are printed in layers over a second conductor to form electrical contacts for light emitting diodes or photovoltaic diodes. In another embodiment, the metallic and semiconductor nanoparticle ink is printed to form electrical contacts for any two, three or more terminal device, such as a transistor or RFID tag.

For example and without limitation, the various metallic inks and/or metallic and semiconductor nanoparticle and other inks disclosed herein may be utilized to form any of the nontransparent conductors or conductive layers for the apparatuses, methods, and systems referred to and disclosed in the following U.S. patent applications, U.S. patents, and PCT Patent Applications, the entire contents of each of which are incorporated herein by reference with the same full force and effect as if set forth in their entireties herein, and with priority claimed for all commonly disclosed subject matter (individually and collectively referred to as the “first related patent applications”): U.S. patent application Ser. No. 13/223,279; U.S. patent application Ser. No. 13/223,286; U.S. patent application Ser. No. 13/223,289; U.S. patent application Ser. No. 13/223,293; U.S. patent application Ser. No. 13/223,294; U.S. patent application Ser. No. 13/223,297; U.S. patent application Ser. No. 13/223,302; U.S. patent application Ser. No. 12/753,888; U.S. patent application Ser. No. 12/753,887; U.S. Pat. No. 7,719,187; U.S. Pat. No. 7,972,031; U.S. Pat. No. 7,992,332; U.S. Pat. No. 8,183,772; U.S. Pat. No. 8,182,303; U.S. Pat. No. 8,127,477. Also for example and without limitation, the various metallic inks and/or metallic and semiconductor nanoparticle and other inks disclosed herein may be utilized to form any of the nontransparent conductors or conductive layers for the apparatuses, methods, and systems referred to and disclosed in the following U.S. patent applications, U.S. patents, and PCT Patent Applications, the entire contents of each of which are incorporated herein by reference with the same full force and effect as if set forth in their entireties herein, and with priority claimed for all commonly disclosed subject matter (individually and collectively referred to as the “second related patent applications”): U.S. patent application Ser. No. 12/560,334; U.S. patent application Ser. No. 12/560,340; U.S. patent application Ser. No. 12/560,355; U.S. patent application Ser. No. 12/560,364; U.S. patent application Ser. No. 12/560,371; U.S. Pat. No. 8,133,768; U.S. patent application Ser. No. 13/025,137; U.S. patent application Ser. No. 13/025,138; PCT Patent Application Serial No. PCT/US2011/50168; PCT Patent Application Serial No. PCT/US2011/50174; and all other applications claiming priority to the foregoing applications and patents.

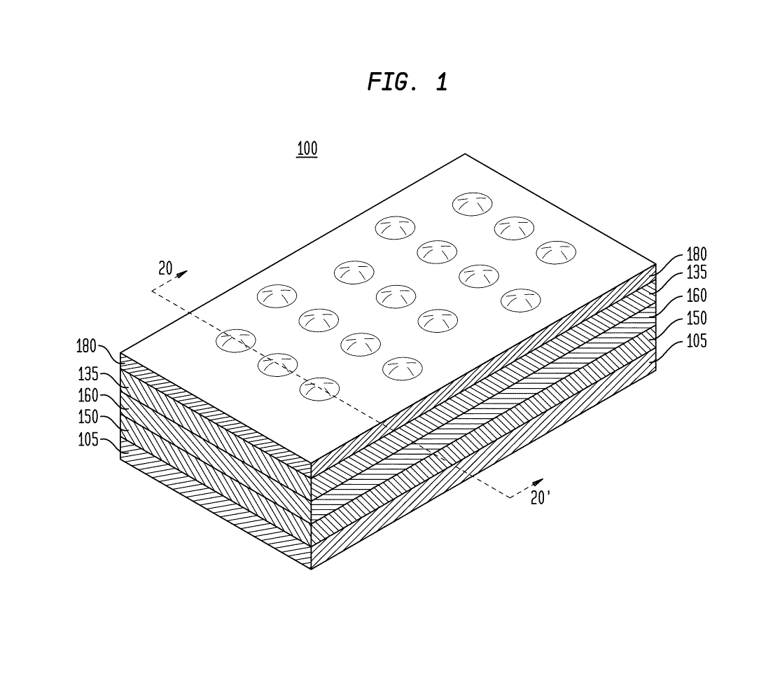

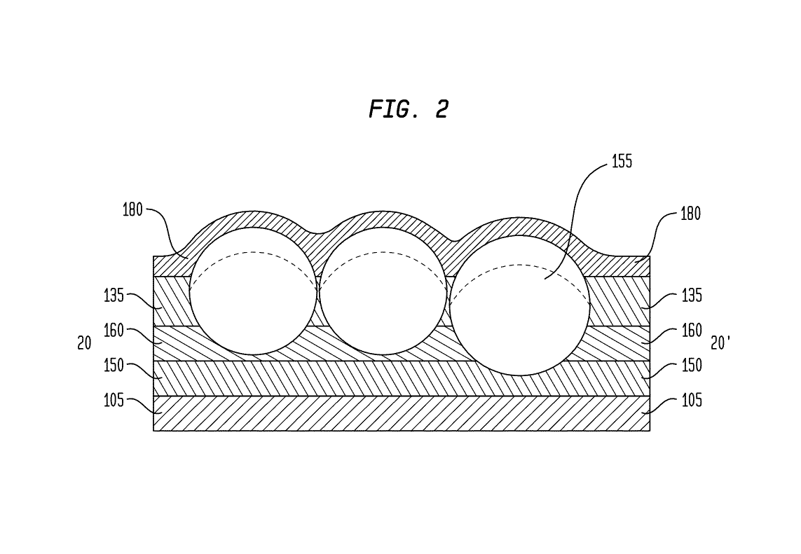

FIG. 1 is a perspective view illustrating a representative apparatus 100 embodiment. FIG. 2 is a cross-sectional view (though the 20-20′ plane of FIG. 1) illustrating a representative apparatus 100 embodiment. The structure or layout of such an apparatus 100, for example and without limitation, may be within the scope of the disclosures of the second related applications, while the novel compositions which may comprise various layers of the apparatus 100 are disclosed herein. As illustrated in FIGS. 1 and 2, an alloyed metallic and semiconductor conductive layer (or conductor) 150 (as a first conductor 150 or first conductive layer 150) has been formed using any of the metallic and semiconductor nanoparticle inks deposited over a second conductor 105, such as an aluminum foil substrate, as described in greater detail below. For example, a metallic and semiconductor nanoparticle ink, a metallic and doped semiconductor nanoparticle ink, an alloyed metallic and semiconductor nanoparticle ink, with or without antioxidants or passivation, may be utilized to form first conductive layer (or conductor) 150.

Continuing to refer to FIGS. 1 and 2, another, optional third conductor or conductive layer 160 has been formed using a polymer-based metallic nanoparticle ink (as described in greater detail below) deposited over the metallic and semiconductor nanoparticle ink, also as described in greater detail below. A plurality of substantially spherical semiconductor particles 155 have been deposited, using a substantially spherical semiconductor particle ink, over the polymer-based metallic nanoparticle ink, when an optional third conductive layer 160 is to be utilized, and otherwise is deposited over the metallic and semiconductor nanoparticle ink, also as described in greater detail below. Also as discussed in greater detail below, the stack or set of layers comprising a conductive substrate (second conductor) 105, metallic and semiconductor nanoparticle ink, optional polymer-based metallic nanoparticle ink, and substantially spherical semiconductor particle ink, are then annealed or alloyed to form the illustrated layers 105, 150, and 160 having the embedded substantially spherical semiconductor particles 155 (some of which may also be embedded in layer 150 as well, as illustrated, and when optional third conductive layer 160 is not included, virtually all or most of the substantially spherical semiconductor particles 155 will be embedded in layer 150, not separately illustrated). It should be noted that the metallic and semiconductor nanoparticles (of the metallic and semiconductor nanoparticle ink) generally combine to form a metal and semiconductor alloy forming conductive layer (or conductor) 150 and generally lose any defined particulate nature, while the polymer-based metallic nanoparticle ink forming conductive layer 160 generally may sinter at the applicable annealing temperatures and maintain some evidence of having been formed from metallic particles.

As disclosed in the second related applications, it also should be noted that a dielectric layer 135 is subsequently deposited (and any excess removed), the substantially spherical semiconductor particles 155 are subsequently converted into diodes, with corresponding pn junctions illustrated by the dashed lines, followed by deposition of additional layers such as transparent conductive layer 180, as disclosed in the second related applications. Not separately illustrated, various enhancement layers, lensing layers or lenses, sealing layers, etc., may also be deposited, as disclosed in the second related applications incorporated by reference herein. The various inks utilized to form these various conductive layers 150 and 160, with or without the embedded substantially spherical semiconductor particles 155, are described in greater detail below.

An exemplary conductor or conductive layer 150, 160, with or without the embedded substantially spherical semiconductor particles 155, is typically a substantially conductive film, layer, strip, electrode, wire or conductive line or trace, having any shape or form factor, and all such shapes and form factors are considered equivalent and within the scope of the disclosure. As an example and without limitation, the first and third conductors 150, 160 are illustrated as substantially flat layers forming a substantially planar apparatus 100. Numerous other shapes and form factors for the conductors or conductive layers 150, 160, are illustrated and discussed in the first and second related applications.

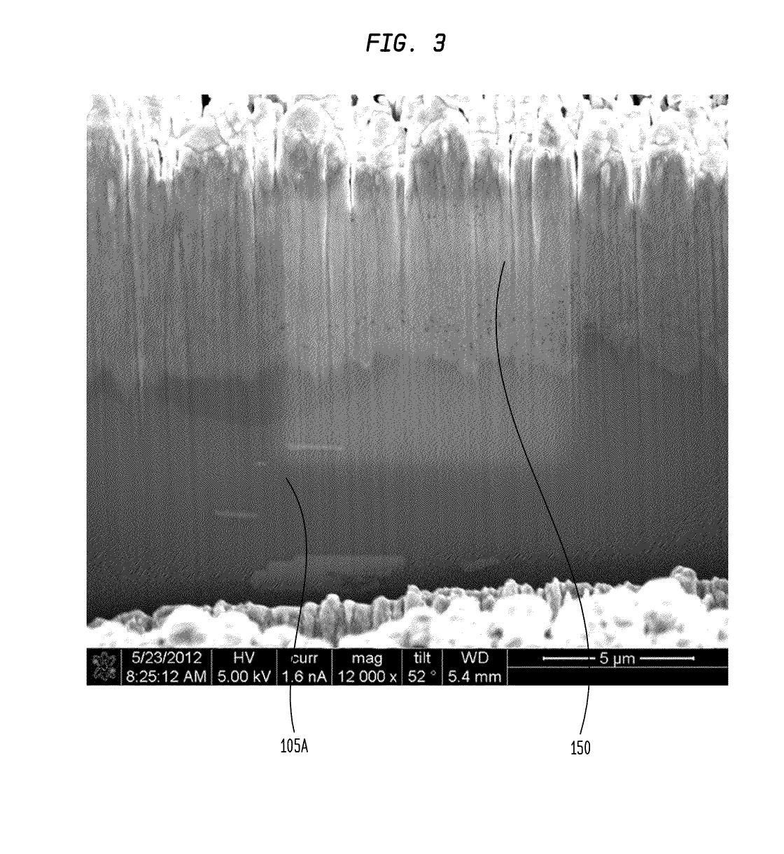

FIG. 3 is a first scanning electron micrograph illustrating a cross-section through a second conductor 105A and a first conductor or conductive layer 150 formed using an exemplary metallic (aluminum) and semiconductor (silicon) nanoparticle ink composition of a representative embodiment. As illustrated, first conductor 105 has been implemented using an aluminum foil 105A, and with the deposited metallic and semiconductor nanoparticle ink and second conductor 105A heated to a temperature about 10° C. below the melting temperature of aluminum. It should be noted that the aluminum foil 105A has remained intact, first conductive layer 150 has formed an alloy of aluminum and silicon, exhibits comparatively low electrical resistance, exhibits limited, if any, defects and significant, virtually seamless connection to second conductor 105A.

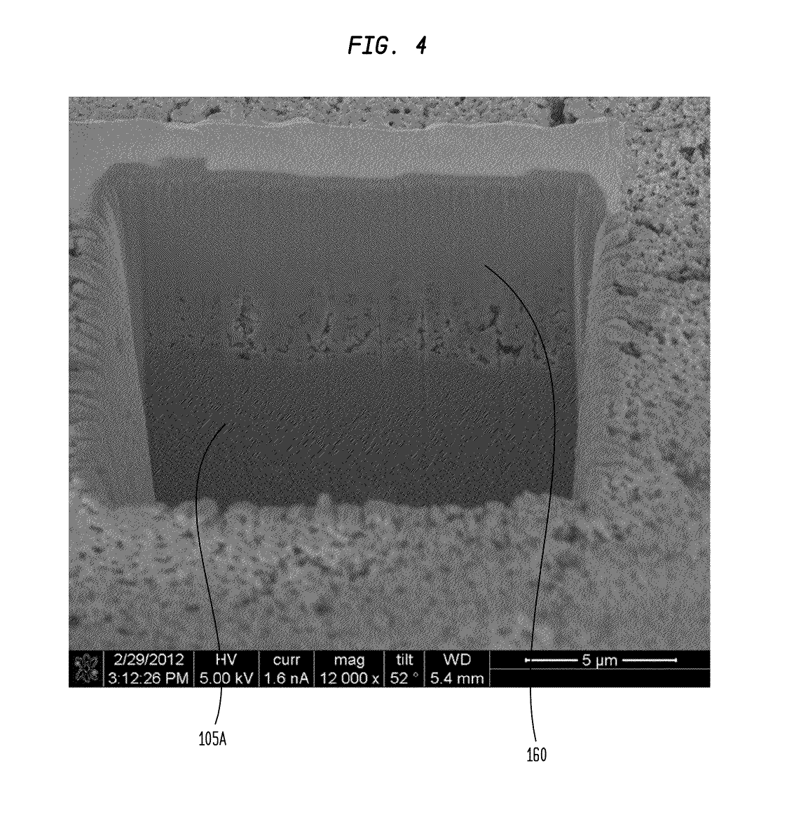

FIG. 4 is a second scanning electron micrograph illustrating a cross-section through a second conductor 105A and a third conductor or conductive layer 160 formed using a polymer-based metallic nanoparticle ink, such as an exemplary metallic (aluminum, or aluminum and tin (or bismuth, or mixtures thereof)) nanoparticle ink composition of a representative embodiment. As illustrated, first conductor 105 has been implemented using an aluminum foil 105A, and with the deposited polymer-based metallic nanoparticle ink and second conductor 105A also heated to a temperature about 10° C. below the melting temperature of aluminum. It should be noted that the aluminum foil 105A has remained intact, this third conductive layer 160 exhibits sintering of the metallic particles while nonetheless providing a significant, virtually seamless connection to second conductor (aluminum foil) 105A, and exhibits comparatively low electrical resistance.

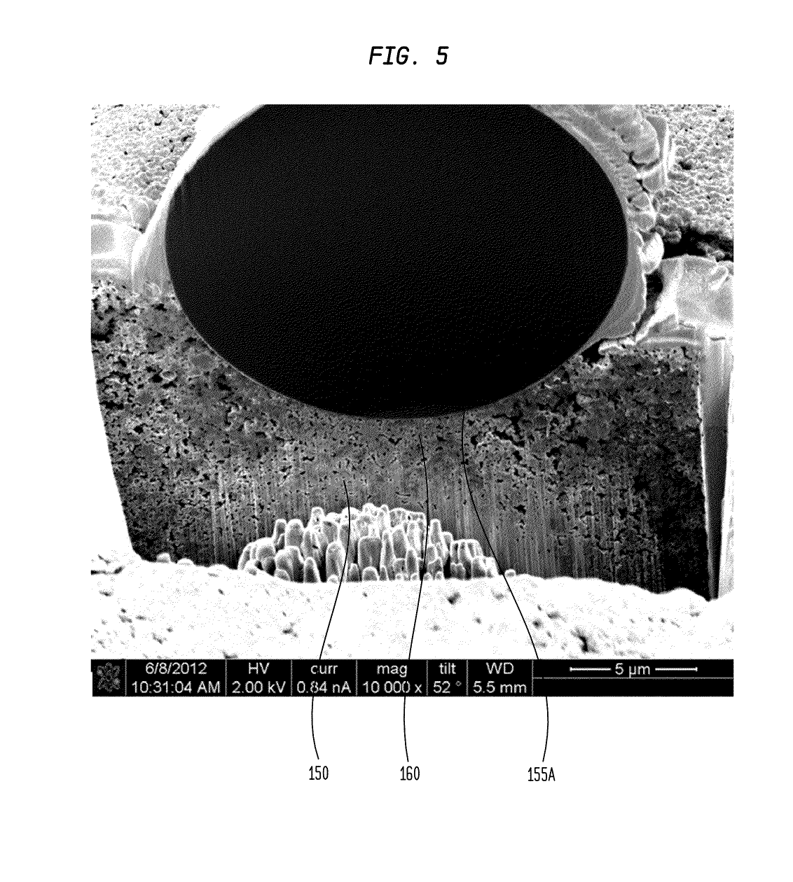

FIG. 5 is a third scanning electron micrograph illustrating a cross-section through a first conductor or conductive layer 150 formed using a representative metallic and semiconductor nanoparticle ink composition, a third conductor or conductive layer 160 formed using a representative polymer-based metallic nanoparticle ink composition, and an embedded substantially spherical silicon particle 155A from a deposited substantially spherical semiconductor particle ink implemented using substantially spherical silicon particles, of a representative embodiment. As illustrated, the deposited substantially spherical semiconductor particle ink, metallic nanoparticle ink, metallic and semiconductor nanoparticle ink, and second conductor 105A also heated to a temperature about 10° C. below the melting temperature of aluminum (e.g., about 600° C.-650° C.). It should be noted that this third conductive layer 160 also exhibits sintering of the metallic particles while nonetheless providing a significant, virtually seamless connection to both first conductor 150 and to substantially spherical silicon particle 155A, aluminum foil 105A has remained intact, and the entire stack of layers 105A, 150, 160 exhibits comparatively low electrical resistance.

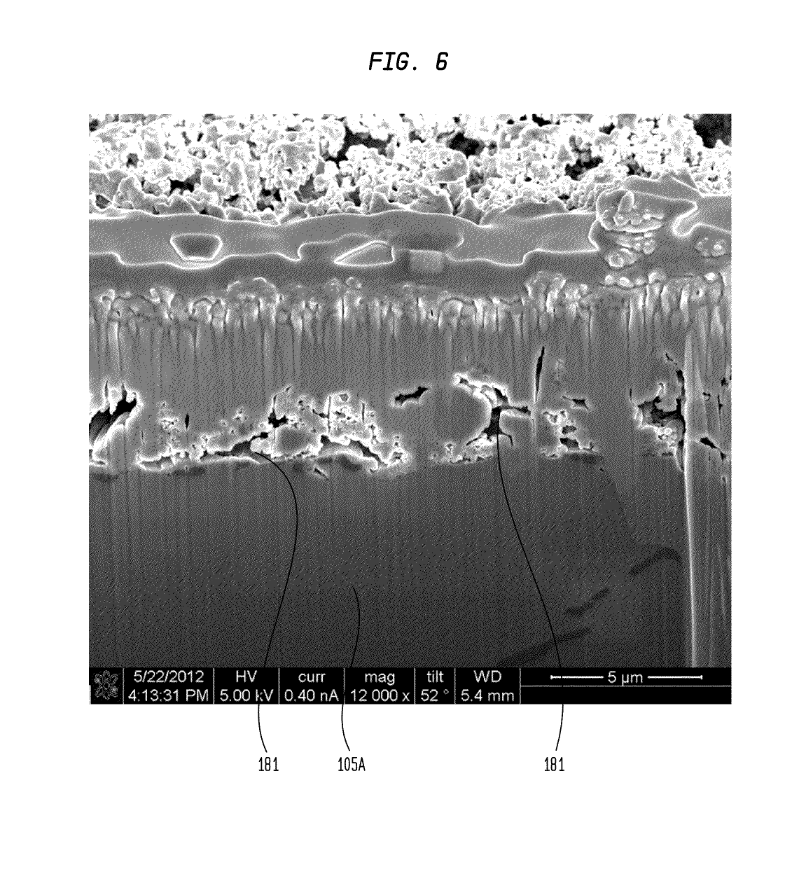

Unexpected effects and generally serendipitous results of using a combination of solvents comprising, first, a polyol such as glycerin, and second, a carboxylic or dicarboxylic acid or mixtures thereof, such as glutaric acid, is illustrated in FIG. 6. FIG. 6 is a fourth scanning electron micrograph illustrating a cross-section through a second conductor and a first conductor or conductive layer formed using conductive ink composition comprising metallic and semiconductor nanoparticles, namely aluminum and silicon particles, in a polymer such as polyvinyl pyrrolidone (“PVP”). The resulting first conductor or conductive layer did not anneal and instead the metallic and semiconductor nanoparticles were sintered, creating a considerably more porous layer exhibiting defects such as voids 181 and insufficient connection to second conductor 105A, and as a consequence, has a higher electrical resistance. FIG. 6 thereby serves to underscore the unexpected effects and generally serendipitous results achieved with the compositions disclosed herein and the layering of the compositions to form first and third conductive layers 150, 160.

Providing another unexpected empirical result, the ester formed from the reaction of a glycol and a dicarboxylic acid, forming a lattice structure, provides both an adhesive function and further allows overprinting of the other components or layers prior to annealing, as mentioned above. In addition, this ester and any remaining polyol and carboxylic acid, except for trace amounts, does not remain in the layer 150 following annealing, unlike other conductive inks in which a significant part of the binding medium remains in the finished conductor.

The conductors or conductive layers 150, 160 may be deposited to have any width and length, with the resulting depth depending to some extent upon the viscosity of the various inks and the sizes (in any dimension) of the metallic nanoparticles and semiconductor nanoparticles (and any additional metallic microparticles and semiconductor microparticles. In addition, one or more layers of a particular ink may be deposited to form any given or selected first conductor or conductive layer 150 or third conductor or conductive layer 160. Referring to FIGS. 1 and 2 in representative embodiments, each of the first conductor or conductive layer 150 and the third conductor or conductive layer 160, once dried and prior to annealing, generally has a substantially thin form factor, generally between about 2 to 15 microns thick, or more particularly between about 3 to 12 microns thick, or more particularly between about 4 to 10 microns thick, or more particularly between about 5 to 7 microns thick.

As mentioned above, in a first representative embodiment, the exemplary metallic nanoparticles may have size (in any dimension) on the order of between about 5 nm to about 1,000 nm. More particularly, in various representative embodiments, the size (in any dimension) of the metallic nanoparticles may vary, for example and without limitation: the plurality of metallic nanoparticles may have a size (in any dimension) between about 5 nm and about 500 nm; or more particularly, may have a size (in any dimension) between about 8 nm and about 300 nm; or more particularly, may have a size (in any dimension) between about 10 nm and about 200 nm; or more particularly, may have a size (in any dimension) between about 10 nm and about 100 nm; or more particularly, may have a size (in any dimension) between about 5 nm and about 50 nm; or more particularly, may have a size (in any dimension) between about 10 nm and about 30 nm. For example and without limitation, in a representative embodiment, the metallic nanoparticles may have a size (in any dimension) between about 10 nm and about 25 nm.

As mentioned above, in a first representative embodiment, the exemplary semiconductor nanoparticles may have size (in any dimension) on the order of between about 5 nm to about 1.5μ. More particularly, in various representative embodiments, the size (in any dimension) of the semiconductor nanoparticles may vary, for example and without limitation: the plurality of semiconductor nanoparticles may have a size (in any dimension) between about 20 nm to about 1.4μ; or more particularly, may have a size (in any dimension) between about 50 nm and about 1.3μ; or more particularly, may have a size (in any dimension) between about 100 nm and about 1.25μ; or more particularly, may have a size (in any dimension) between about 500 nm and about 1.25μ; or more particularly, may have a size (in any dimension) between about 750 nm and about 1.25μ, or more particularly, may have a size (in any dimension) between about 800 nm and about 1.2μ. For example, in a representative embodiment, the metallic nanoparticles may have a size (in any dimension) between about 10 nm and about 25 nm and the semiconductor nanoparticlesmay have a size (in any dimension) between about 800 nm and about 1.2μ.

As mentioned above, in a second representative embodiment, the exemplary additional metallic microparticles may have size (in any dimension) on the order of between about 1μ to about 10μ to 20μ or potentially more. More particularly, in various representative embodiments, the size (in any dimension) of the metallic microparticles may vary, and may vary in different combinations with the semiconductor microparticles and with the metallic nanoparticles and semiconductor nanoparticles, for example and without limitation: the metallic microparticles may have a size (in any dimension) between about 1μ, to about 8μ; or more particularly, may have a size (in any dimension) between about 1μ, to about 7μ; or more particularly, may have a size (in any dimension) between about 1μ, to about 6μ; or more particularly, may have a size (in any dimension) between about 1μ to about 5μ. For example, in an exemplary embodiment, the metallic nanoparticles may have a size (in any dimension) between about 10 nm and about 30 nm and the semiconductor nanoparticles and semiconductor microparticles collectively may have a size (in any dimension) between about 5 nm and about 20μ. Also for example, in another exemplary embodiment, the metallic nanoparticles may have a size (in any dimension) between about 10 nm and about 30 nm and the metallic microparticles may have a size (in any dimension) between about 1μ, to about 10μ, and may or may not further include any semiconductor nanoparticles or semiconductor microparticles.

As mentioned above, in a second representative embodiment, the exemplary additional semiconductor microparticles may have size (in any dimension) on the order of between about 1μ to about 20μ or potentially more. More particularly, in various exemplary embodiments, the size (in any dimension) of the semiconductor microparticles may vary, and may vary in different combinations with the metallic microparticles and with the metallic nanoparticles and semiconductor nanoparticles, for example and without limitation: the semiconductor microparticles may have a size (in any dimension) between about 1μ, to about 18μ; or more particularly, may have a size (in any dimension) between about 1μ to about 15μ; or more particularly, may have a size (in any dimension) between about 1μ, to about 10μ; or more particularly, may have a size (in any dimension) between about 1μ to about 5μ. For example, in a representative embodiment, the semiconductor nanoparticles may have a size (in any dimension) between about 800 nm and about 1.2μ and the metallic nanoparticles, metallic microparticles and semiconductor microparticles collectively may have a size (in any dimension) between about 5 nm and about 10-20μ. Also for example, in another exemplary embodiment, the semiconductor nanoparticles may have a size (in any dimension) between about 800 nm and about 1.2μ and the semiconductor microparticles may have a size (in any dimension) between about 1.2μ to about 20μ, and may or may not further include any metallic nanoparticles or metallic microparticles.

Various nanoparticle and microparticle sizes for any of the various alloys of metal and semiconductor and/or doped semiconductor used in alloyed metallic and semiconductor nanoparticle ink or metallic and doped semiconductor nanoparticle ink respectively, or used in any of the conductive polyol carboxylic acid-based inks, may also have any of the above-mentioned ranges.

These sizes of the various metallic nanoparticles, semiconductor nanoparticles, metallic microparticles, semiconductor microparticles, and/or alloyed metallic and semiconductor (or doped semiconductor) nanoparticles and microparticles, however, are not absolute; for example, further experimentation may indicate that either smaller or larger particle sizes are or may be advantageous. As a result, no size limitation should be inferred unless a size is specifically claimed, and otherwise any and all particle sizes are within the scope of the disclosure and claims.

The selection of the sizes of the metallic nanoparticles, semiconductor nanoparticles, metallic microparticles, semiconductor microparticles, and/or alloyed metallic and semiconductor (or doped semiconductor) nanoparticles and microparticles for any of the inks may also depend upon the type of printing or other deposition to be utilized. For example and without limitation, for screen printing, the sizes may be selected for the pore or hole size of the screen or mesh, to pass through and not become caught in the screen.

The dimensions of the various particles may be measured, for example, using a light microscope (which may also include measuring software). As additional examples, the dimensions of the particles may be measured using, for example, a scanning electron microscope (SEM), or Horiba's LA-920. The Horiba LA-920 instrument uses the principles of low-angle Fraunhofer Diffraction and Light Scattering to measure the particle size and distribution in a dilute solution of particles. All particle sizes are measured in terms of their number average particle diameters and lengths, as there may be significant outliers in the fabrication of any of these particles.

In addition, any of the metallic nanoparticles, semiconductor nanoparticles, metallic microparticles, semiconductor microparticles, and/or alloyed metallic and semiconductor (or doped semiconductor) nanoparticles and microparticles may have any of various shapes, unless expressly specified to the contrary, such as irregular (e.g., typical unrefined or unshaped particles or powders), flaked, fibers, filaments, spherical, oblong, oval or ovoid, cubic, spherical, substantially spherical, near spherical, faceted, any organic shapes, cubic, or various prismatic shapes (e.g., trapezoidal, triangular, pyramidal, etc.), and so on.

The exemplary metallic nanoparticles and metallic microparticles may be comprised of a wide variety of materials, and a referred to as “metallic” to indicate substantially high conductivity. In an exemplary embodiment, metallic nanoparticles and metallic microparticles are comprised of one or more metals (e.g., aluminum, copper, silver, gold, nickel, palladium, tin, platinum, lead, zinc, bismuth, iron, titanium, etc.), alone or in combination with each other, such as an alloy, for example and without limitation. Provided that other conductors and/or conductive compounds or materials do not dissipate under various selected processing temperatures for a selected embodiment, other combinations of different types of conductors and/or conductive compounds or materials (e.g., ink, polymer, carbon nanotubes (“CNTs”), elemental metal, etc.) could also be utilized to form metallic nanoparticles and metallic microparticles. In representative embodiments, metals have been utilized because of selected processing temperatures, e.g., about 600° C.-650° C., which is sufficiently high to dissipate CNTs and many polymers or viscosity modifiers. Multiple layers and/or types of metal or other conductive materials may be combined to form the metallic nanoparticles and metallic microparticles.

The representative semiconductor nanoparticles and semiconductor microparticles also may be comprised of a wide variety of materials, with the choice of semiconductor material typically based upon the type of semiconductor to which an electrical contact will be made or a desired annealing temperature. In representative embodiments, semiconductor nanoparticles and semiconductor microparticles are comprised of any type of semiconductor element, material or compound, which may be a single type of semiconductor or a combination of different types of semiconductors, such as silicon, gallium arsenide (GaAs), gallium nitride (GaN), or any inorganic or organic semiconductor material, and in any form, including GaP, InAlGaP, InAlGaP, AlInGaAs, InGaNAs, AlInGaSb, also for example and without limitation. Also in addition, for contacts to be formed on a wafer or wafer material, the semiconductor nanoparticles and/or semiconductor microparticles potentially could be comprised of such a wafer material, such as silicon, GaAs, GaN, sapphire, silicon carbide, SiO₂, also for example and without limitation. In representative embodiments, the exemplary semiconductor nanoparticles and semiconductor microparticles also may be doped (such as to form metallic and doped semiconductor nanoparticle ink), such as n doped or p doped, or heavily doped, such as n+ or p+ silicon, n+ or p+GaN, for example and without limitation, using any dopant material known or developed in the future, including without limitation boron, arsenic, phosphorus, and gallium. In addition, the representative semiconductor nanoparticles and semiconductor microparticles also may have any type of crystalline lattice structure or may be amorphous, such as a <111> or <110> silicon crystal structure or orientation or amorphous silicon, also for example and without limitation. Combinations of different types of semiconductors and/or semiconductor compounds or materials also may also be utilized to form representative semiconductor nanoparticles and semiconductor microparticles. Multiple layers and/or types of semiconductor or other semiconductor materials may be combined to form the representative semiconductor nanoparticles and semiconductor microparticles.

As mentioned above with reference to FIGS. 3-6 and as discussed in greater detail below, unexpected results have been achieved utilizing the metallic and semiconductor (e.g., silicon) nanoparticle ink, along with selected first and second solvents (discussed below), providing superior electrical connectivity and comparatively low resistance.

It should also be noted that while many of the semiconductor nanoparticles and semiconductor microparticles are discussed in which silicon and GaN may be or are the selected semiconductors, other inorganic or organic semiconductors may be utilized equivalently and are within the scope of the disclosure. Examples of inorganic semiconductors include, without limitation: silicon, germanium, and mixtures thereof titanium dioxide, silicon dioxide, zinc oxide, indium-tin oxide, antimony-tin oxide, and mixtures thereof II-VI semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof III-V semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof and group IV semiconductors including hydrogen terminated silicon, carbon, germanium, and alpha-tin, and combinations thereof.

In an exemplary embodiment, the plurality of semiconductor nanoparticles and/or semiconductor microparticles comprises at least one inorganic semiconductor selected from the group consisting of: silicon, gallium arsenide (GaAs), gallium nitride (GaN), GaP, InAlGaP, InAlGaP, AlInGaAs, InGaNAs, and AlInGaSb. In another exemplary embodiment and depending upon the processing temperatures to be utilized, the plurality of semiconductor nanoparticles and/or semiconductor microparticles potentially could comprise at least one organic semiconductor selected from the group consisting of: π-conjugated polymers, poly(acetylene)s, poly(pyrrole)s, poly(thiophene)s, polyanilines, polythiophenes, poly(p-phenylene sulfide), poly(para-phenylene vinylene)s (PPV) and PPV derivatives, poly(3-alkylthiophenes), polyindole, polypyrene, polycarbazole, polyazulene, polyazepine, poly(fluorene)s, polynaphthalene, polyaniline, polyaniline derivatives, polythiophene, polythiophene derivatives, polypyrrole, polypyrrole derivatives, polythianaphthene, polythianaphthane derivatives, polyparaphenylene, polyparaphenylene derivatives, polyacetylene, polyacetylene derivatives, polydiacethylene, polydiacetylene derivatives, polyparaphenylenevinylene, polyparaphenylenevinylene derivatives, polynaphthalene, polynaphthalene derivatives, polyisothianaphthene (PITN), polyheteroarylenvinylene (ParV) in which the heteroarylene group is thiophene, furan or pyrrol, polyphenylene-sulphide (PPS), polyperinaphthalene (PPN), polyphthalocyanine (PPhc), and their derivatives, copolymers thereof and mixtures thereof. In representative embodiments, the above-mentioned organic semiconductors have not been utilized because of the selected processing temperatures, e.g., about 650° C., as they would tend to burn off or otherwise dissipate.

The exemplary metallic nanoparticles, semiconductor nanoparticles, metallic microparticles, and semiconductor microparticles may also be functionalized with a wide variety of compounds to aid their dispersion in a liquid or gel and/or to prevent oxidation of the particles. In a representative embodiment, any of the metallic nanoparticles and/or microparticles may be passivated or functionalized to prevent or diminish oxidation by having a complete or full coating, a substantial coating, or at least a partial coating of various compounds such as benzotriazole, zinc phosphate, zinc dithiophosphate, tannic acid, and/or hexafluoroacetylacetone, for example and without limitation.

The representative compositions may also include one or more antioxidants including, for example and without limitation: N,N-diethylhydroxylamine, ascorbic acid, hydrazine, hexamine, and/or phenylenediamine.

The exemplary metallic nanoparticles, semiconductor nanoparticles, metallic microparticles, semiconductor microparticles, and alloyed metallic and semiconductor nanoparticles and microparticles may be fabricated using any fabrication techniques which are known currently or which are developed in the future. Exemplary metallic nanoparticles and metallic microparticles, and semiconductor microparticles are commercially available and have been obtained from several suppliers, including SkySpring Nanomaterials, Inc. and Nanostructured & Amorphous Materials, Inc., both of Houston, Tex., US. Exemplary semiconductor nanoparticles and semiconductor microparticles are commercially available and have been obtained from several suppliers, including REC Silicon, Inc. of Moses Lake, Wash., US and MEMC Electronic Materials, Inc. of St. Peters, Mo., US.

In the following examples, reference may be made to FIGS. 1 and 2 as representative examples of how any and each of the following compositions may be utilized in practice. For example and without limitation, the Metallic and Semiconductor Nanoparticle Ink and/or Conductive Polyol Carboxylic Acid-Based Ink Examples may be deposited over a second conductor 105 to form a first conductor or conductive layer 150, Polymer-Based Metallic Nanoparticle Ink Examples may be utilized to form a second conductor or conductive layer 160, and Substantially Spherical Semiconductor Particle Ink Examples may be utilized to deposit substantially spherical semiconductor particles 155. Following such deposition and drying of these three or more layers, the entire stack of layers may be annealed, as mentioned above.

Metallic and Semiconductor Nanoparticle Ink Example 1:
A composition comprising:
a plurality of metallic nanoparticles;
a plurality of semiconductor nanoparticles; and
a solvent.

Metallic and Semiconductor (Alloyed) Nanoparticle Ink Example 2:
A composition comprising:
a plurality of nanoparticles, each nanoparticle comprising an alloy of a metal and a semiconductor; and
a solvent.

Metallic and (Doped) Semiconductor Nanoparticle Ink Example 3:
A composition comprising:
a plurality of metallic nanoparticles;
a plurality of doped semiconductor nanoparticles; and
a solvent.

Metallic and Semiconductor Nanoparticle Ink Example 4:
A composition comprising:
a plurality of passivated metallic nanoparticles;
a plurality of semiconductor nanoparticles; and
a solvent.

Metallic and Semiconductor Nanoparticle Ink Example 5:
A composition comprising:
a plurality of metallic nanoparticles;
a plurality of semiconductor nanoparticles;
a solvent; and
an antioxidant.

Metallic and Semiconductor Nanoparticle Ink Example 6:
A composition comprising:
a plurality of metallic nanoparticles;
a plurality of metallic microparticles;
a plurality of semiconductor nanoparticles; and
a solvent.

Metallic and Semiconductor Nanoparticle Ink Example 7:
A composition comprising:
a plurality of metallic nanoparticles;
a plurality of metallic microparticles;
a plurality of semiconductor nanoparticles;
a plurality of semiconductor microparticles; and
a solvent.

Metallic and Semiconductor Nanoparticle Ink Example 8:
A composition comprising:
a plurality of metallic nanoparticles;
a plurality of semiconductor nanoparticles;
a solvent; and
a viscosity modifier, which also may be a second solvent different form the first solvent.

Metallic and Semiconductor Nanoparticle Ink Example 9:
A composition comprising:
a plurality of metallic nanoparticles having a size (in any dimension) between about 5 nm and about 1,000 nm;
a plurality of semiconductor nanoparticles having a size (in any dimension) between about 5 nm and about 1.5μ; and
a solvent.

Metallic and Semiconductor Nanoparticle Ink Example 10:
A composition comprising:
a plurality of metallic nanoparticles having a size (in any dimension) between about 5 nm and about 1,000 nm;
a plurality of metallic microparticles having a size (in any dimension) between about 1μ, and about 10μ;
a plurality of semiconductor nanoparticles having a size (in any dimension) between about 5 nm and about 1.5μ; and
a solvent.

Metallic and Semiconductor Nanoparticle Ink Example 11:
A composition comprising:
a plurality of metallic nanoparticles having a size (in any dimension) between about 5 nm and about 1,000 nm;
a plurality of metallic microparticles having a size (in any dimension) between about 1μ, and about 10μ;
a plurality of semiconductor nanoparticles having a size (in any dimension) between about 5 nm and about 1.5μ;
a plurality of semiconductor microparticles having a size (in any dimension) between about 1.5μ and about 20μ; and
a solvent.

Metallic and Semiconductor Nanoparticle Ink Example 12:
A composition comprising:
a plurality of metallic nanoparticles;
a plurality of semiconductor nanoparticles;
a first solvent; and
a second solvent, the second solvent different from the first solvent.

Metallic and Semiconductor Nanoparticle Ink Example 13:
A composition comprising:
a plurality of metallic nanoparticles;
a plurality of semiconductor nanoparticles;
a first solvent;
a second solvent, the second solvent different from the first solvent; and
a third solvent, the third solvent different from the first and second solvents.

Metallic and Semiconductor Nanoparticle Ink Example 14:
A composition comprising:
a plurality of metallic nanoparticles;
a plurality of semiconductor nanoparticles;
a first solvent comprising a polyol or mixtures thereof and
a second solvent comprising a carboxylic acid or mixtures thereof.

Metallic and Semiconductor Nanoparticle Ink Example 15:
A composition comprising:
a plurality of metallic nanoparticles;
a plurality of semiconductor nanoparticles;
a first solvent comprising a polyol or mixtures thereof; and
a second solvent comprising a dicarboxylic acid or mixtures thereof.

Metallic and Doped Semiconductor Nanoparticle Ink Example 16:
A composition comprising:
a plurality of metallic nanoparticles;
a plurality of doped semiconductor nanoparticles;
a first solvent comprising a polyol or mixtures thereof; and
a second solvent comprising a carboxylic or dicarboxylic acid or mixtures thereof.

Metallic and Semiconductor Alloy Nanoparticle Ink Example 17:
A composition comprising:
a plurality of particles, each particle comprising an alloy of a metal and a semiconductor;
a first solvent comprising a polyol or mixtures thereof; and
a second solvent comprising a carboxylic or dicarboxylic acid or mixtures thereof.

Metallic and Semiconductor Alloy Nanoparticle Ink Example 18:
A composition comprising:
a plurality of particles, each particle comprising an alloy of a metal and a semiconductor;
a first solvent comprising a polyol or mixtures thereof; and
a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

Metallic and Semiconductor Alloy Nanoparticle Ink Example 19:
A composition comprising:
a plurality of particles, each particle comprising an alloy of a metal and a semiconductor;
a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; and
a second solvent comprising a carboxylic or dicarboxylic acid or mixtures thereof.

Metallic and Semiconductor Nanoparticle Ink Example 20:
A composition comprising:
a plurality of metallic nanoparticles;
a plurality of semiconductor nanoparticles;
a first solvent comprising glycerin; and
a second solvent comprising glutaric acid.

Metallic and Semiconductor Nanoparticle Ink Example 21:
A composition comprising:
a plurality of metallic nanoparticles present in an amount of between about 3% to 20% by weight;
a plurality of semiconductor nanoparticles present in an amount of between about 10% to 50% by weight;
a first solvent comprising glycerin and present in an amount of between about 30% to 60% by weight; and
a second solvent comprising glutaric acid and present in an amount of between about 10% to 40% by weight.

Metallic and Semiconductor Nanoparticle Ink Example 22:
A composition comprising:
a plurality of metallic nanoparticles present in an amount of between about 5% to 10% by weight;
a plurality of semiconductor nanoparticles present in an amount of between about 20% to 40% by weight;
a first solvent comprising glycerin and present in an amount of between about 40% to 50% by weight; and
a second solvent comprising glutaric acid and present in an amount of between about 15% to 25% by weight.

Metallic and Semiconductor Nanoparticle Ink Example 23:
A composition comprising:
a plurality of metallic nanoparticles present in an amount of between about 7% to 9% by weight;
a plurality of semiconductor nanoparticles present in an amount of between about 27.5% to 32.5% by weight;
a first solvent comprising glycerin and present in an amount of between about 42% to 46% by weight; and
a second solvent comprising glutaric acid and present in an amount of between about 17% to 21% by weight.

Metallic and Semiconductor Nanoparticle Ink Example 24:
A composition comprising:
a plurality of metallic nanoparticles and microparticles and a semiconductor nanoparticles and microparticles and present in an amount of between about 40% to 95% by weight;
a first solvent comprising glycerin and present in an amount of between about 3.5% to 35% by weight;
a second solvent comprising glutaric acid and present in an amount of between about 0.5% to 15% by weight; and
a third, volatile solvent present in an amount of between about 0.5% to 10% by weight.

Metallic and Semiconductor Nanoparticle Ink Example 25:
A composition comprising:
a plurality of metallic nanoparticles, each metallic nanoparticle having at least a partial coating selected from the group consisting of: benzotriazole, zinc phosphate, zinc dithiophosphate, tannic acid, hexafluoroacetylacetone, and mixtures thereof;
a plurality of semiconductor nanoparticles; and
a solvent.

Metallic and Semiconductor Nanoparticle Ink Example 26:
A composition comprising:
a plurality of metallic nanoparticles;
a plurality of semiconductor nanoparticles;
a solvent; and
an antioxidant selected from the group consisting of: N,N-diethylhydroxylamine, ascorbic acid, hydrazine, hexamine, phenylenediamine, and mixtures thereof.

Conductive Polyol Carboxylic Acid-Based Ink Example 1:
A composition comprising:
a plurality of conductive particles;
a first solvent comprising a polyol; and
a second solvent comprising any carboxylic acid (including dicarboxylic, tricarboxylic, etc.).

Conductive Polyol Carboxylic Acid-Based Ink Example 2:
A composition comprising:
a plurality of conductive particles;
a first solvent comprising a polyol; and
a second solvent comprising a dicarboxylic acid.

Conductive Polyol Carboxylic Acid-Based Ink Example 3:
A composition comprising:
a plurality of conductive particles;
a first solvent comprising glycerin; and
a second solvent comprising glutaric acid.

Conductive Polyol Carboxylic Acid-Based Ink Example 4:
A composition comprising:
a plurality of metallic particles;
a first solvent comprising a polyol; and
a second solvent comprising a carboxylic or dicarboxylic acid or mixtures thereof.

Conductive Polyol Carboxylic Acid-Based Ink Example 5:
A composition comprising:
a plurality of semiconductor particles;
a first solvent comprising a polyol; and
a second solvent comprising a carboxylic or dicarboxylic acid or mixtures thereof.

Conductive Polyol Carboxylic Acid-Based Ink Example 6:
A composition comprising:
a plurality of metallic nanoparticles;
a first solvent comprising a polyol; and
a second solvent comprising a carboxylic or dicarboxylic acid or mixtures thereof.

Conductive Polyol Carboxylic Acid-Based Ink Example 7:
A composition comprising:
a plurality of semiconductor nanoparticles;
a first solvent comprising a polyol; and
a second solvent comprising a carboxylic or dicarboxylic acid or mixtures thereof.

Polymer-Based Metallic Nanoparticle Ink Example 1:
A composition comprising:
a plurality of metallic nanoparticles or microparticles;
a solvent; and
a viscosity modifier.

Polymer-Based Metallic Nanoparticle Ink Example 2:
A composition comprising:
a plurality of metallic nanoparticles or microparticles comprising a plurality of different metals;
a solvent; and
a viscosity modifier.

Polymer-Based Metallic Nanoparticle Ink Example 3:
A composition comprising:
a plurality of metallic nanoparticles or microparticles comprising aluminum and tin (or bismuth, or mixtures thereof) and present in an amount between 30% to 50% by weight;
a solvent present in an amount between 50% and 80% by weight and selected from the group consisting of isopropanol, tetramethyl urea, 1-butanol, n-methylpyrrolidone, cyclohexanol, cyclohexanone, cyclopentanone, and mixtures thereof; and
a viscosity modifier present in an amount between 0.1% and 5% by weight.

Polymer-Based Metallic Nanoparticle Ink Example 4:
A composition comprising:
a first plurality of metallic nanoparticles or microparticles comprising aluminum and present in an amount between 30% to 40% by weight;
a second plurality of metallic nanoparticles or microparticles comprising tin (or bismuth, or mixtures thereof) and present in an amount between 3% to 7% by weight;
a solvent present in an amount between 55% and 70% by weight and selected from the group consisting of isopropanol, tetramethyl urea, 1-butanol, n-methylpyrrolidone, cyclohexanol, cyclohexanone, cyclopentanone, and mixtures thereof; and
a viscosity modifier present in an amount between 0.1% and 2% by weight and selected from the group consisting of polyvinyl pyrrolidone (PVP), polyvinyl alcohol, a polyimide, and mixtures thereof.

Substantially Spherical Semiconductor Particle Ink Example 1:
A composition comprising:
a plurality of substantially spherical semiconductor particles;
a first solvent comprising a polyol; and
a second solvent comprising a carboxylic or dicarboxylic acid or mixtures thereof.

Substantially Spherical Semiconductor Particle Ink Example 2:
A composition comprising:
a plurality of substantially spherical semiconductor particles;
a first solvent comprising glycerin; and
a second solvent comprising glutaric acid.

Substantially Spherical Semiconductor Particle Ink Example 3:
A composition comprising:
a plurality of substantially spherical semiconductor particles present in an amount of between about 50% to 70% by weight;
a first solvent comprising glycerin and present in an amount of between about 15% to 35% by weight;
a second solvent comprising glutaric acid and present in an amount of between about 5% to 15% by weight; and
a third solvent comprising tetramethylurea, or butanol, or isopropanol, or mixtures thereof, and present in an amount of between about 1% to 10% by weight.

Substantially Spherical Semiconductor Particle Ink Example 4:
A composition comprising:
a plurality of substantially spherical semiconductor particles present in an amount of between about 55% to 65% by weight;
a first solvent comprising glycerin and present in an amount of between about 20% to 30% by weight;
a second solvent comprising glutaric acid and present in an amount of between about 8% to 13% by weight; and
a third solvent comprising tetramethylurea, or butanol, or isopropanol, or mixtures thereof, and present in an amount of between about 3% to 7% by weight.

Substantially Spherical Semiconductor Particle Ink Example 5:
A composition comprising:
a plurality of substantially spherical semiconductor particles present in an amount of between about 57.5% to 62.5% by weight;
a first solvent comprising glycerin and present in an amount of between about 23% to 27% by weight;
a second solvent comprising glutaric acid and present in an amount of between about 10% to 12% by weight; and
a third solvent comprising tetramethylurea, or butanol, or isopropoanol, or mixtures thereof, and present in an amount of between about 4% to 6% by weight.

Substantially Spherical Semiconductor Particle Ink Example 6:
A composition comprising:
a plurality of substantially spherical semiconductor particles present in an amount of between about 55% to 65% by weight;
one or more solvents present in an amount of between about 35% to 45% by weight and selected from the group consisting of glycerin, glutaric acid, terpineol, tetramethylurea, butanol, isopropoanol, and mixtures thereof.

Apparent from the various Examples, a wide variety of compositions are within the scope of the disclosure. In various exemplary embodiments, a representative metallic and semiconductor nanoparticle ink comprises a plurality of metallic nanoparticles and a plurality of semiconductor nanoparticles which are dispersed in one or more solvents (such as glycerin, another polyol, glutaric acid, another dicarboxylic acid, for example), and possibly also additional metallic microparticles and/or semiconductor microparticles. One or more solvents (as first, second, third fourth, etc., solvents) may be used. In a representative embodiment, the solvent comprises one or more solvents selected from the group consisting of: water; alcohols such as methanol, ethanol, N-propanol (including 1-propanol, 2-propanol (isopropanol or IPA), 1-methoxy-2-propanol), butanol (including 1-butanol, 2-butanol (isobutanol)), pentanol (including 1-pentanol, 2-pentanol, 3-pentanol), hexanol (including 1-hexanol, 2-hexanol, 3-hexanol), octanol, N-octanol (including 1-octanol, 2-octanol, 3-octanol), tetrahydrofurfuryl alcohol (THFA), cyclohexanol, cyclopentanol, terpineol; lactones such as butyl lactone; ethers such as methyl ethyl ether, diethyl ether, ethyl propyl ether, and polyethers; ketones, including diketones and cyclic ketones, such as cyclohexanone, cyclopentanone, cycloheptanone, cyclooctanone, acetone, benzophenone, acetylacetone, acetophenone, cyclopropanone, isophorone, methyl ethyl ketone; esters such ethyl acetate, dimethyl adipate, proplyene glycol monomethyl ether acetate, dimethyl glutarate, dimethyl succinate, glycerin acetate, carboxylates; carbonates such as propylene carbonate; polyols (or liquid polyols), glycerols and other polymeric polyols or glycols such as glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; carboxylic acids, including alkyl carboxylic acids and higher-order carboxylic acids (such as dicarboxylic acids, tricarboxylic acids, etc.), such as formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid; tetramethyl urea, n-methylpyrrolidone, acetonitrile, tetrahydrofuran (THF), dimethyl formamide (DMF), N-methyl formamide (NMF), dimethyl sulfoxide (DMSO); thionyl chloride; sulfuryl chloride; and mixtures thereof acids, including organic acids (in addition to carboxylic acids, dicarboxylic acids, tricarboxylic acids, alkyl carboxylic acids, etc.), such as hydrochloric acid, sulfuric acid, carbonic acid; and bases such as ammonium hydroxide, sodium hydroxide, potassium hydroxide; and mixtures thereof.

In addition, a solvent may also function as a viscosity modifier and vice-versa, such as glycerin, glutaric acid, cyclohexanol, terpineol and n-methylpyrrolidone, for example and without limitation. For example, glutaric acid is a solid at room temperature, and may be heated with glycerin to about 70-80° C., with the combination of solvents remaining a liquid when cooled to room temperature, and then mixed with the metallic and/or semiconductor particles.

In various exemplary embodiments, the selection of a first (or second or third) solvent generally is based upon at least several properties or characteristics, such as its evaporation rate, which should be slow enough to allow sufficient screen residence (for screen printing) of the metallic and semiconductor nanoparticle ink or to meet other printing parameters. In various exemplary embodiments, an exemplary evaporation rate is less than one (<1, as a relative rate compared with butyl acetate), or more specifically, between 0.0001 and 0.9999. Another characteristic is its ability to allow overprinting when dry, such as overprinting of a polymer-based metallic nanoparticle ink and overprinting of a plurality of semiconductor spheres, any of which may also be dispersed in a solvent and/or a viscosity modifier. Another characteristic is its wettability of substrates, such as an aluminum or silicon substrate, such as any of the third solvents indicated in the examples.

One or more viscosity modifiers, binders, resins or thickeners (as a viscosity modifier) (or equivalently, a viscous compound, a viscous resin, a viscous agent, a viscous polymer, a viscous resin, a viscous binder, a thickener, and/or a rheology modifier) may be used, for example and without limitation: polymers (or equivalently, polymeric precursors or polymerizable precursors) such as polyvinyl pyrrolidone (PVP, also referred to or known as polyvinyl pyrrolidinone), polyvinyl alcohol, polyvinylidene fluoride, polyvynylidene fluoride-trifluoroethylene, polytetrafluoroethylene, polydimethylsiloxane, polyethelene, polypropylene, polyethylene oxide, polypropylene oxide, polyethylene glycolhexafluoropropylene, polyethylene terefphtalatpolyacrylonitryle, polyvinylalcogel, polyvinylpyrrolidone, polyvynilchloride, polyvinyl butyral, polyvinylcaprolactam, polyvinyl chloride; polyimide polymers, copolymers (including aliphatic, aromatic and semi-aromatic polyimides) and other polymers and polymeric precursors such as polyamide, polyaramides, polyacrylamide; acrylate and (meth)acrylate polymers and copolymers such as polymethylmethacrylate, polyacrylonitrile, acrylonitrile butadiene styrene, allylmethacrylate, polystyrene, polybutadiene, polybutylene terephthalate, polycarbonate, polychloroprene, polyethersulfone, nylon, styrene-acrylonitrile resin; glycols such as ethylene glycols, diethylene glycol, polyethylene glycols, propylene glycols, dipropylene glycols, glycol ethers, glycol ether acetates; clays such as hectorite clays, garamite clays, organo-modified clays; saccharides and polysaccharides such as guar gum, xanthan gum, starch, butyl rubber, agarose, pectin; celluloses and modified celluloses such as hydroxy methylcellulose, methylcellulose, ethyl cellulose, propyl methylcellulose, methoxy cellulose, methoxy methylcellulose, methoxy propyl methylcellulose, hydroxy propyl methylcellulose, carboxy methylcellulose, hydroxy ethylcellulose, ethyl hydroxyl ethylcellulose, cellulose ether, cellulose ethyl ether, chitosan; fumed silica (such as Cabosil), silica powders and modified ureas such as BYK® 420 (available from BYK Chemie GmbH); and mixtures thereof. As mentioned above, some of the viscosity modifiers may also function as solvents and vice-versa, such as the various glycols, and therefore are included in the various listings of exemplary solvents and viscosity modifiers. In an exemplary embodiment, the PVP utilized has a molecular weight between about 50,000 to about 3 million MW, or more particularly between about 100,000 to 2 million MW, or more particularly between about 500,000 to 1.5 million MW, or more particularly between about 750,000 to 1.25 million MW, while the PVA has a molecular weight of about 133K, or more generally between about 50,000 to 250K MW, and may be obtained from Polysciences, Inc. of Warrington, Pa. USA. In various embodiments, E-3 and E-10 cellulose resins available from The Dow Chemical Company (www.dow.com) and Hercules Chemical Company, Inc. (www.herchem.com) may be utilized. Other viscosity modifiers may be used, as well as particle addition to control viscosity, as described in Lewis et al., Patent Application Publication Pub. No. US 2003/0091647. Other viscosity modifiers or binders may also be utilized.

It should be noted that in an exemplary embodiment, such as a Polymer-Based Metallic Nanoparticle Ink Example, a viscosity modifier such as PVP may perform additional functions, such as providing cushioning and adhesion for the substantially spherical semiconductor particles 155.

As mentioned above and as described in the Examples, the exemplary metallic nanoparticles, semiconductor nanoparticles, metallic microparticles, and semiconductor microparticles may also be functionalized with a wide variety of compounds to aid their dispersion in a liquid or gel and/or to prevent oxidation of the particles. In a representative embodiment, any of the metallic nanoparticles and/or microparticles may be passivated or functionalized to prevent or diminish oxidation by having a complete or full coating, a substantial coating, or at least a partial coating of various compounds such as benzotriazole, zinc phosphate, zinc dithiophosphate, tannic acid, and/or hexafluoroacetylacetone, for example and without limitation.

Also as mentioned above and as described in the Examples, the representative compositions may also include one or more antioxidants including, for example and without limitation: N,N-diethylhydroxylamine, ascorbic acid, hydrazine, hexamine, and/or phenylenediamine.

Referring to the Examples, there are a wide variety of exemplary metallic and semiconductor nanoparticle ink and other compositions within the scope of the present disclosure. Each of the various ink compositions disclosed herein may have a viscosity substantially about 50 centipoise (cps) to about 25,000 cps at about 25° C. (about room temperature), and may be adjusted depending upon the deposition technique to be utilized, for example: for screen printing, the composition may have a viscosity between about 100 centipoise (cps) and 25,000 cps at 25° C., or more specifically between about 100 cps and 15,000 cps at 25° C., or more specifically between about 200 cps and 12,000 cps at 25° C., or more specifically between about 300 cps and 5,000 cps at 25° C., or more specifically between about 400 cps and 1,000 cps at 25° C., or more specifically between about 2,000 cps and 10,000 cps at 25° C., (or between about 500 cps to 60,000 cps at a refrigerated temperature (e.g., 5-10° C.)). Other viscosities may be more suitable for other types of deposition such as flexographic printing, gravure printing, and slot die coating, for example and without limitation. Depending upon the viscosity, the resulting composition may be referred to equivalently as a liquid or as a gel suspension of metallic and semiconductor nanoparticles, and any reference to liquid or gel herein shall be understood to mean and include the other.

In addition, the resulting viscosity of the metallic and semiconductor nanoparticle ink will generally vary depending upon the type of printing process to be utilized and may also vary depending upon the particle composition and size. For example, for flexographic printing, each of the various ink compositions disclosed herein may have a viscosity between about 100 centipoise (cps) and 10,000 cps at room temperature, or more specifically between about 200 centipoise (cps) and 4,000 cps at room temperature, or more specifically between about 500 centipoise (cps) and 3,000 cps at room temperature, or more specifically between about 1,800 centipoise (cps) and 2,200 cps at room temperature, or more specifically between about 2,000 centipoise (cps) and 6,000 cps at room temperature, or more specifically between about 2,500 centipoise (cps) and 4,500 cps at room temperature, or more specifically between about 2,000 centipoise (cps) and 4,000 cps at room temperature.

Viscosity may be measured in a wide variety of ways. For purposes of comparison, the various specified and/or claimed ranges of viscosity herein have been measured using a Brookfield viscometer (available from Brookfield Engineering Laboratories of Middleboro, Mass., USA) at a shear stress of about 200 pascals (or more generally between 190 and 210 pascals), in a water jacket at about 25° C., using a spindle SC4-27 at a speed of about 10 rpm (or more generally between 1 and 30 rpm, particularly for refrigerated fluids, for example and without limitation).

Referring to Examples, each of the various ink compositions disclosed herein may further comprise one or more additional solvents (such as second or third solvents). The balance any of the various ink compositions disclosed herein is generally another, second or third solvent (or fourth or more solvents), depending upon the embodiment, such as a glycol or polyol, a dicarboxylic acid, or isopropanol, tetramethyl urea, 1-butanol, n-methylpyrrolidone, cyclohexanol, cyclohexanone, cyclopentanone, deionized water, or any of the other solvents described above or any other solvents which may be found to be suitable, and any descriptions of percentages herein shall assume that the balance of the composition is such a second, third or fourth solvent, for example and without limitation, such as a polyol, a dicarboxylic acid, isopropanol, tetramethyl urea, cyclohexanol, cyclohexanone, cyclopentanone, n-methylpyrrolidone, 1-butanol or water, and all described percentages are based on weight, rather than volume or some other measure. It should also be noted that most of the compositions disclosed herein may all be mixed in a typical atmospheric setting, without requiring any particular composition of air or other contained or filtered environment, except that the addition of metallic particles such as aluminum, for the various metallic and semiconductor nanoparticle ink suspensions, is performed in an inert atmosphere to diminish or prevent oxidation.

A particular advantage of this formulation using glycerin and glutaric acid, for examples of solvents, is that the various percentages of metallic particles and semiconductor particles and solvents such as glycerin, glutaric acid and any third or more solvents may be adjusted independently of the other.

Additional surfactants or non-foaming agents for printing may be utilized in any of the various ink compositions disclosed herein as an option, but are not required for proper functioning and exemplary printing.

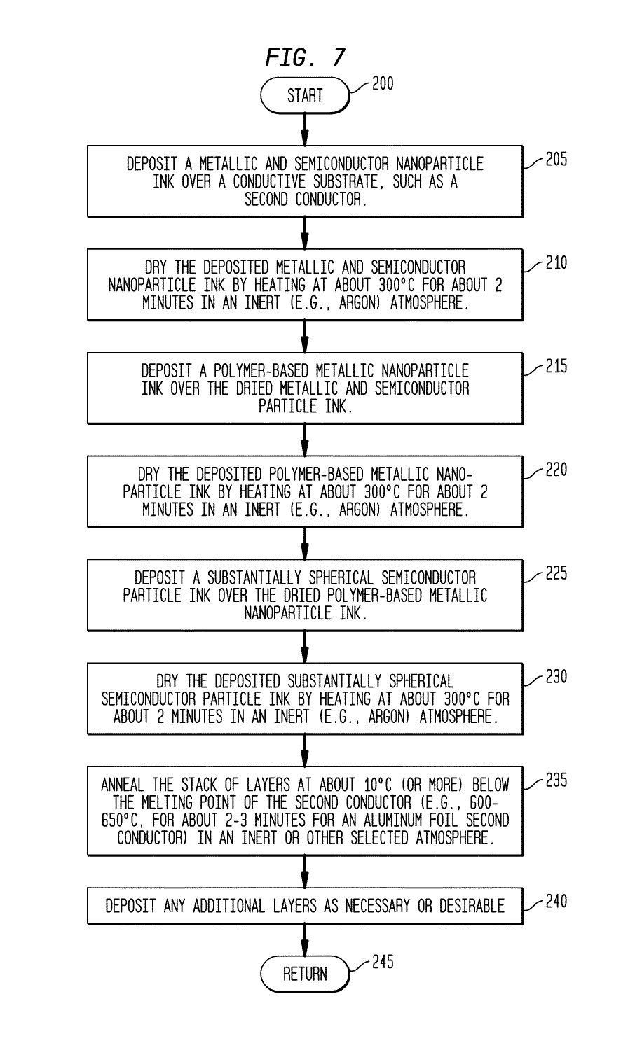

FIG. 7 is a flow chart illustrating a method embodiment in accordance with the teachings of the present invention, for forming or otherwise manufacturing an apparatus 100 or components of an apparatus 100, and provides a useful summary. Beginning with start step 200, the method deposits a metallic and semiconductor nanoparticle ink over a second conductor 105, such as through printing, step 205. The layer of metallic and semiconductor nanoparticle ink is dried by heating for about two minutes at about 300° C. in a selected atmosphere, such as argon, step 210. As mentioned above, the dried thickness of the metallic and semiconductor nanoparticle ink is generally about 5-7 microns. A polymer-based metallic nanoparticle ink is then deposited over the dried metallic and semiconductor nanoparticle ink, step 215. The layers of the polymer-based metallic nanoparticle ink and the metallic and semiconductor nanoparticle ink are then dried by heating, also for about two minutes at about 300° C. in a selected atmosphere, such as argon, step 220. As mentioned above, the dried thickness of the polymer-based metallic nanoparticle ink is also generally about 5-7 microns. As indicated above, steps 215 and 220 are optional, and are utilized when a third conductive layer 160 is to be implemented. Next, in step 225, a substantially spherical semiconductor particle ink is then deposited over the polymer-based metallic nanoparticle ink (which is over the dried metallic and semiconductor nanoparticle ink), or over the dried metallic and semiconductor nanoparticle ink when a layer 160 will not be included. The layers of the substantially spherical semiconductor particle ink, the optional polymer-based metallic nanoparticle ink and the metallic and semiconductor nanoparticle ink are then dried by heating, also for about two minutes at about 300° C. in a selected atmosphere, such as argon, step 230. The layers of the substantially spherical semiconductor particle ink, the polymer-based metallic nanoparticle ink, the metallic and semiconductor nanoparticle ink, and the second conductor 105 are then annealed generally up to about 10° C. below any melting point of the second conductor 105, such as for about 2-3 minutes at about 600° C.-650° C. for an aluminum foil second conductor 105A, in an inert or other selected atmosphere, such as argon, step 235. Following step 235, additional layers may be deposited as necessary or desirable to form an apparatus 100, step 240, such as a dielectric layer 135, a transparent conductive layer 180, a lens layer, a sealing layer, etc., as described in the second related applications, and the method may end, return step 245.

With this annealing of step 235, first conductor (or conductive layer) 150 and third conductor (or conductive layer) 160 are formed. As mentioned above, the first conductor (or conductive layer) 150 is generally an alloy of whatever metal and semiconductor have been utilized in the metallic and semiconductor nanoparticle ink, such as an alloy of aluminum and silicon, and further may contain trace amounts (e.g., less than 1-2% or lower) of other compounds, such as trace amounts of solvents or other additives. Generally, however, due to the annealing temperature, most other compounds have been dissipated, such as the solvents utilized in each of the metallic and semiconductor nanoparticle ink, the polymer-based metallic nanoparticle ink, and the substantially spherical semiconductor particle ink, and any of the polymers or other viscosity modifiers of the polymer-based metallic nanoparticle ink. Also with this annealing of step 235, a substantially conductive electrical coupling is formed between the second conductor 105 and these overprinted layers 150, 160, and spherical semiconductor particles 155, without significant or substantial deformation or loss of any substrate comprising such spherical semiconductor particles 155, allowing a comparatively low impedance electrical coupling to the second conductor 105.

As a further consequence, the first, second, and third conductors or conductive layer 150, 105, 160 do not require further processing, such as compression through nip rollers, to be sufficiently conductive with comparatively low sheet resistance while establishing ohmic contacts.

Any types of deposition processes may be utilized. As a consequence, as used herein, “deposition” includes any and all printing, coating, rolling, spraying, layering, sputtering, plating, spin casting (or spin coating), vapor deposition, lamination, affixing and/or other deposition processes, whether impact or non-impact, known in the art. “Printing” includes any and all printing, coating, rolling, spraying, layering, spin coating, lamination and/or affixing processes, whether impact or non-impact, known in the art, and specifically includes, for example and without limitation, screen printing, inkjet printing, electro-optical printing, electroink printing, photoresist and other resist printing, thermal printing, laser jet printing, magnetic printing, pad printing, flexographic printing, hybrid offset lithography, Gravure and other intaglio printing, die slot deposition, for example. All such processes are considered deposition processes herein and may be utilized. The exemplary deposition or printing processes do not require significant manufacturing controls or restrictions. No specific temperatures or pressures are required. Some clean room or filtered air may be useful, but potentially at a level consistent with the standards of known printing or other deposition processes. For consistency, however, such as for proper alignment (registration) of the various successively deposited layers forming the various embodiments, relatively constant temperature (with a possible exception, discussed below) and humidity may be desirable.

The first conductor or conductive layer 150 formed from the annealed metallic and/or metallic and semiconductor nanoparticle ink may be utilized in a wide variety of applications, namely, an application involving a conductor or a conductive ink or polymer. Various applications are also illustrated in the first and second related applications, incorporated by reference herein in their entireties. Numerous additional applications will be apparent to those having skill in the art, including innumerable variations in the ways in which the first conductor or conductive layer 150 may be formed, with all such variations considered equivalent and within the scope of the disclosure. In addition, for other various embodiments, the first conductor or conductive layer 150 may be deposited as a single or continuous layer, such as through coating or printing, for example.

As may be apparent from the disclosure, an exemplary first conductor or conductive layer 150 may be designed and fabricated to be highly flexible and deformable, potentially even foldable, stretchable and potentially wearable, rather than rigid. For example, an exemplary first conductor or conductive layer 150 may comprise flexible, foldable, and wearable clothing, or a flexible lamp, or a wallpaper lamp, without limitation. With such flexibility, an exemplary first conductor or conductive layer 150 may be rolled, such as a poster, or folded like a piece of paper, and fully functional when re-opened. Also for example, with such flexibility, an exemplary first conductor or conductive layer 150 may have many shapes and sizes, and be configured for any of a wide variety of styles and other aesthetic goals.

Although the invention has been described with respect to specific embodiments thereof, these embodiments are merely illustrative and not restrictive of the invention. In the description herein, numerous specific details are provided, such as examples of electronic components, electronic and structural connections, materials, and structural variations, to provide a thorough understanding of embodiments of the present invention. One skilled in the relevant art will recognize, however, that an embodiment of the invention can be practiced without one or more of the specific details, or with other apparatus, systems, assemblies, components, materials, parts, etc. In other instances, well-known structures, materials, or operations are not specifically shown or described in detail to avoid obscuring aspects of embodiments of the present invention. One having skill in the art will further recognize that additional or equivalent method steps may be utilized, or may be combined with other steps, or may be performed in different orders, any and all of which are within the scope of the claimed invention. In addition, the various Figures are not drawn to scale and should not be regarded as limiting.

Reference throughout this specification to “one embodiment”, “an embodiment”, or a specific “embodiment” means that a particular feature, structure, or characteristic described in connection with the embodiment is included in at least one embodiment and not necessarily in all embodiments, and further, are not necessarily referring to the same embodiment. Furthermore, the particular features, structures, or characteristics of any specific embodiment may be combined in any suitable manner and in any suitable combination with one or more other embodiments, including the use of selected features without corresponding use of other features. In addition, many modifications may be made to adapt a particular application, situation or material to the essential scope and spirit of the present invention. It is to be understood that other variations and modifications of the embodiments of the present invention described and illustrated herein are possible in light of the teachings herein and are to be considered part of the spirit and scope of the present invention.

It will also be appreciated that one or more of the elements depicted in the Figures can also be implemented in a more separate or integrated manner, or even removed or rendered inoperable in certain cases, as may be useful in accordance with a particular application. Integrally formed combinations of components are also within the scope of the invention, particularly for embodiments in which a separation or combination of discrete components is unclear or indiscernible. In addition, use of the term “coupled” herein, including in its various forms such as “coupling” or “couplable”, means and includes any direct or indirect electrical, structural or magnetic coupling, connection or attachment, or adaptation or capability for such a direct or indirect electrical, structural or magnetic coupling, connection or attachment, including integrally formed components and components which are coupled via or through another component.

The dimensions and values disclosed herein are not to be understood as being strictly limited to the exact numerical values recited. Instead, unless otherwise specified, each such dimension is intended to mean both the recited value and a functionally equivalent range surrounding that value. For example, a dimension disclosed as “40 mm” is intended to mean “about 40 mm.”

All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Furthermore, any signal arrows in the drawings/Figures should be considered only exemplary, and not limiting, unless otherwise specifically noted. Combinations of components of steps will also be considered within the scope of the present invention, particularly where the ability to separate or combine is unclear or foreseeable. The disjunctive term “or”, as used herein and throughout the claims that follow, is generally intended to mean “and/or”, having both conjunctive and disjunctive meanings (and is not confined to an “exclusive or” meaning), unless otherwise indicated. As used in the description herein and throughout the claims that follow, “a”, “an”, and “the” include plural references unless the context clearly dictates otherwise. Also as used in the description herein and throughout the claims that follow, the meaning of “in” includes “in” and “on” unless the context clearly dictates otherwise.

The foregoing description of illustrated embodiments of the present invention, including what is described in the summary or in the abstract, is not intended to be exhaustive or to limit the invention to the precise forms disclosed herein. From the foregoing, it will be observed that numerous variations, modifications and substitutions are intended and may be effected without departing from the spirit and scope of the novel concept of the invention. It is to be understood that no limitation with respect to the specific methods and apparatus illustrated herein is intended or should be inferred. It is, of course, intended to cover by the appended claims all such modifications as fall within the scope of the claims.

It is claimed:

1. A composition comprising:
a plurality of metallic nanoparticles;
a plurality of semiconductor nanoparticles; and
a first solvent.

2. The composition of claim 1, wherein the plurality of metallic nanoparticles have a size in any dimension between about 5 nm and about 1.0μ.

3. The composition of claim 1, wherein the plurality of semiconductor nanoparticles have a size in any dimension between about 5 nm and about 1.5μ.

4. The composition of claim 1, wherein the plurality of metallic nanoparticles have a size in any dimension between about 5 nm and about 200 nm and the plurality of semiconductor nanoparticles have sizes in any dimension between about 5 nm and about 200 nm.

5. The composition of claim 1, further comprising:
a plurality of metallic microparticles having sizes in any dimension between about 1μ and about 20μ.

6. The composition of claim 1, further comprising:
a plurality of semiconductor microparticles having sizes in any dimension between about 1μ and about 20μ.

7. The composition of claim 1, wherein each nanoparticle of the plurality of metallic nanoparticles and of the plurality of semiconductor nanoparticles comprises an alloy of a metal and a semiconductor.

8. The composition of claim 1, wherein each semiconductor nanoparticle of the plurality of semiconductor nanoparticles further comprises a doped semiconductor.

9. The composition of claim 1, wherein each semiconductor nanoparticle of the plurality of semiconductor nanoparticles further comprises a dopant selected from the group consisting of: boron, arsenic, phosphorus, gallium, and mixtures thereof.

10. The composition of claim 1, wherein the plurality of metallic nanoparticles comprises at least one metal selected from the group consisting of: aluminum, copper, silver, gold, nickel, palladium, tin, platinum, lead, zinc, bismuth, alloys thereof, and mixtures thereof.

11. The composition of claim 1, wherein the plurality of semiconductor nanoparticles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof.

12. The composition of claim 1, wherein the plurality of semiconductor nanoparticles comprises at least one semiconductor selected from the group consisting of: silicon, germanium, and mixtures thereof; titanium dioxide, silicon dioxide, zinc oxide, indium-tin oxide, antimony-tin oxide, and mixtures thereof; II-VI semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof; III-V semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof; and group IV semiconductors including hydrogen terminated silicon, carbon, germanium, and alpha-tin, and combinations thereof.

13. The composition of claim 1, wherein at least some nanoparticles of the plurality of metallic nanoparticles are surface passivated to reduce oxidation.

14. The composition of claim 1, wherein at least some nanoparticles of the plurality of metallic nanoparticles are passivated with at least a partial coating selected from the group consisting of: benzotriazole, zinc phosphate, zinc dithiophosphate, tannic acid, hexafluoroacetylacetone, and mixtures thereof.

15. The composition of claim 1, further comprising:
an antioxidant.

16. The composition of claim 1, further comprising:
an antioxidant selected from the group consisting of: N,N-diethylhydroxylamine, ascorbic acid, hydrazine, hexamine, phenylenediamine, and mixtures thereof

17. The composition of claim 1, wherein the first solvent comprises at least one solvent selected from the group consisting of: water; alcohols such as methanol, ethanol, N-propanol (including 1-propanol, 2-propanol (isopropanol or IPA), 1-methoxy-2-propanol), butanol (including 1-butanol, 2-butanol (isobutanol)), pentanol (including 1-pentanol, 2-pentanol, 3-pentanol), hexanol (including 1-hexanol, 2-hexanol, 3-hexanol), octanol, N-octanol (including 1-octanol, 2-octanol, 3-octanol), tetrahydrofurfuryl alcohol (THFA), cyclohexanol, cyclopentanol, terpineol; lactones such as butyl lactone; ethers such as methyl ethyl ether, diethyl ether, ethyl propyl ether, and polyethers; ketones, including diketones and cyclic ketones, such as cyclohexanone, cyclopentanone, cycloheptanone, cyclooctanone, acetone, benzophenone, acetylacetone, acetophenone, cyclopropanone, isophorone, methyl ethyl ketone; esters such ethyl acetate, dimethyl adipate, proplyene glycol monomethyl ether acetate, dimethyl glutarate, dimethyl succinate, glycerin acetate, carboxylates; carbonates such as propylene carbonate; polyols (or liquid polyols), glycerols and other polymeric polyols or glycols such as glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; carboxylic acids, including alkyl carboxylic acids and higher-order carboxylic acids (such as dicarboxylic acids, tricarboxylic acids), such as formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid; tetramethyl urea, n-methylpyrrolidone, acetonitrile, tetrahydrofuran (THF), dimethyl formamide (DMF), N-methyl formamide (NMF), dimethyl sulfoxide (DMSO); thionyl chloride; sulfuryl chloride; and mixtures thereof. acids, including organic acids (in addition to carboxylic acids, dicarboxylic acids, tricarboxylic acids, alkyl carboxylic acids), such as hydrochloric acid, sulfuric acid, carbonic acid; and bases such as ammonium hydroxide, sodium hydroxide, potassium hydroxide; and mixtures thereof.

18. The composition of claim 1, wherein the first solvent comprises a polyol or mixtures thereof.

19. The composition of claim 1, wherein the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof.

20. The composition of claim 1, wherein the first solvent comprises a carboxylic acid, or a dicarboxylic acid, or mixtures thereof.

21. The composition of claim 1, wherein the first solvent comprises a carboxylic acid selected from the group consisting of: formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

22. The composition of claim 1, wherein the first solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

23. The composition of claim 1, further comprising:
a second solvent different from the first solvent.

24. The composition of claim 23, wherein the first solvent comprises a polyol or mixtures thereof, and the second solvent comprises a carboxylic or dicarboxylic acid or mixtures thereof.

25. The composition of claim 23, wherein:
the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and
the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof

26. The composition of claim 23, wherein the first solvent comprises a polyol or mixtures thereof, and wherein the second solvent comprises at least one organic acid selected from the group consisting of: carboxylic acids, dicarboxylic acids, tricarboxylic acids, alkyl carboxylic acids, acetic acid, oxalic acid, mellitic acid, formic acid, chloroacetic acid, benzoic acid, trifluoroacetic acid, propanoic acid, butanoic acid; and mixtures thereof.

27. The composition of claim 23, wherein the second solvent comprises at least one solvent selected from the group consisting of: water; alcohols such as methanol, ethanol, N-propanol (including 1-propanol, 2-propanol (isopropanol or IPA), 1-methoxy-2-propanol), butanol (including 1-butanol, 2-butanol (isobutanol)), pentanol (including 1-pentanol, 2-pentanol, 3-pentanol), hexanol (including 1-hexanol, 2-hexanol, 3-hexanol), octanol, N-octanol (including 1-octanol, 2-octanol, 3-octanol), tetrahydrofurfuryl alcohol (THFA), cyclohexanol, cyclopentanol, terpineol; lactones such as butyl lactone; ethers such as methyl ethyl ether, diethyl ether, ethyl propyl ether, and polyethers; ketones, including diketones and cyclic ketones, such as cyclohexanone, cyclopentanone, cycloheptanone, cyclooctanone, acetone, benzophenone, acetylacetone, acetophenone, cyclopropanone, isophorone, methyl ethyl ketone; esters such ethyl acetate, dimethyl adipate, proplyene glycol monomethyl ether acetate, dimethyl glutarate, dimethyl succinate, glycerin acetate, carboxylates; carbonates such as propylene carbonate; polyols (or liquid polyols), glycerols and other polymeric polyols or glycols such as glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; carboxylic acids, including alkyl carboxylic acids and higher-order carboxylic acids (such as dicarboxylic acids, tricarboxylic acids), such as formic acid, acetic acid, mellitic acid, chloroacetic acid, dichloroacetic acid, trichloroacetic acid, benzoic acid, trifluoroacetic acid, propanoic acid, butanoic acid; ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid; tetramethyl urea, n-methylpyrrolidone, acetonitrile, tetrahydrofuran (THF), dimethyl formamide (DMF), N-methyl formamide (NMF), dimethyl sulfoxide (DMSO); thionyl chloride; sulfuryl chloride; and mixtures thereof acids, including organic acids (in addition to carboxylic acids, dicarboxylic acids, tricarboxylic acids, alkyl carboxylic acids), such as hydrochloric acid, sulfuric acid, carbonic acid; and bases such as ammonium hydroxide, sodium hydroxide, potassium hydroxide; and mixtures thereof.

28. The composition of claim 23, wherein:
the plurality of metallic nanoparticles are comprised of aluminum;
the plurality of semiconductor nanoparticles are comprised of silicon;
the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; and
the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

29. The composition of claim 23, wherein:
the plurality of metallic nanoparticles are present in an amount of about 3% to 20% by weight;
the plurality of semiconductor nanoparticles are present in an amount of about 10% to 50% by weight;
the first solvent is present in an amount of about 30% to 60% by weight and comprises a polyol or mixtures thereof; and
the second solvent is present in an amount of about 10% to 40% by weight and comprises a carboxylic or dicarboxylic acid or mixtures thereof.

30. The composition of claim 23, wherein:
the plurality of metallic nanoparticles are present in an amount of about 5% to 10% by weight;
the plurality of semiconductor nanoparticles are present in an amount of about 20% to 40% by weight;
the first solvent is present in an amount of about 40% to 50% by weight and comprises a polyol or mixtures thereof; and
the second solvent is present in an amount of about 15% to 25% by weight and comprises a carboxylic or dicarboxylic acid or mixtures thereof.

31. The composition of claim 23, wherein:
the plurality of metallic nanoparticles are present in an amount of about 7% to 9% by weight;
the plurality of semiconductor nanoparticles are present in an amount of about 27.5% to 32.5% by weight;
the first solvent is present in an amount of about 42% to 46% by weight and comprises glycerin; and
the second solvent is present in an amount of about 17% to 21% by weight and comprises glutaric acid.

32. The composition of claim 1, wherein the composition has a viscosity substantially between about 50 cps and about 25,000 cps at about 25° C.

33. The composition of claim 1, wherein the composition has a viscosity substantially between about 100 cps and about 10,000 cps at about 25° C.

34. A method of using the composition of claim 1, the method comprising:
printing and annealing the composition to form an electrical conductor.

35. A composition comprising:
a plurality of metallic nanoparticles;
a plurality of semiconductor nanoparticles;
a first solvent comprising a polyol or mixtures thereof; and
a second solvent comprising a carboxylic or dicarboxylic acid or mixtures thereof.

36. The composition of claim 35, wherein the plurality of metallic nanoparticles have a size in any dimension between about 5 nm and about 1.0μ and the plurality of semiconductor nanoparticles have a size in any dimension between about 5 nm and about 1.5μ.

37. The composition of claim 35, further comprising:
a plurality of metallic microparticles having sizes in any dimension between about 1μ and about 20μ; and
a plurality of semiconductor microparticles having sizes in any dimension between about 1μ and about 20μ.

38. The composition of claim 35, wherein each nanoparticle of the plurality of metallic nanoparticles and of the plurality of semiconductor nanoparticles comprises an alloy of a metal and a semiconductor.

39. The composition of claim 35, wherein each semiconductor nanoparticle of the plurality of semiconductor nanoparticles further comprises a dopant selected from the group consisting of: boron, arsenic, phosphorus, gallium, and mixtures thereof.

40. The composition of claim 35, wherein the plurality of metallic nanoparticles comprises at least one metal selected from the group consisting of: aluminum, copper, silver, gold, nickel, palladium, tin, platinum, lead, zinc, bismuth, alloys thereof, and mixtures thereof.

41. The composition of claim 35, wherein the plurality of semiconductor nanoparticles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof.

42. The composition of claim 35, wherein the plurality of semiconductor nanoparticles comprises at least one semiconductor selected from the group consisting of: silicon, germanium, and mixtures thereof; titanium dioxide, silicon dioxide, zinc oxide, indium-tin oxide, antimony-tin oxide, and mixtures thereof; II-VI semiconductors, which are compounds of at least one divalent metal (zinc, cadmium, mercury and lead) and at least one divalent non-metal (oxygen, sulfur, selenium, and tellurium) such as zinc oxide, cadmium selenide, cadmium sulfide, mercury selenide, and mixtures thereof; III-V semiconductors, which are compounds of at least one trivalent metal (aluminum, gallium, indium, and thallium) with at least one trivalent non-metal (nitrogen, phosphorous, arsenic, and antimony) such as gallium arsenide, indium phosphide, and mixtures thereof; and group IV semiconductors including hydrogen terminated silicon, carbon, germanium, and alpha-tin, and combinations thereof.

43. The composition of claim 35, wherein at least some nanoparticles of the plurality of metallic nanoparticles are passivated with at least a partial coating selected from the group consisting of: benzotriazole, zinc phosphate, zinc dithiophosphate, tannic acid, hexafluoroacetylacetone, and mixtures thereof.

44. The composition of claim 35, further comprising:
an antioxidant selected from the group consisting of: N,N-diethylhydroxylamine, ascorbic acid, hydrazine, hexamine, phenylenediamine, and mixtures thereof

45. The composition of claim 35, wherein the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof.

46. The composition of claim 35, wherein the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

47. The composition of claim 35, wherein:
the plurality of metallic nanoparticles are comprised of aluminum;
the plurality of semiconductor nanoparticles are comprised of silicon;
the first solvent comprises a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol; and
the second solvent comprises a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

48. The composition of claim 35, wherein:
the plurality of metallic nanoparticles are present in an amount of about 7% to 9% by weight;
the plurality of semiconductor nanoparticles are present in an amount of about 27.5% to 32.5% by weight;
the first solvent is present in an amount of about 42% to 46% by weight and comprises glycerin; and
the second solvent is present in an amount of about 17% to 21% by weight and comprises glutaric acid.

49. A composition comprising:
a plurality of metallic nanoparticles;
a plurality of semiconductor nanoparticles;
a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and
a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

50. The composition of claim 49, wherein the plurality of metallic nanoparticles have a size in any dimension between about 5 nm and about 1.0μ and the plurality of semiconductor nanoparticles have a size in any dimension between about 5 nm and about 1.5μ.

51. The composition of claim 49, further comprising:
a plurality of metallic microparticles having sizes in any dimension between about 1μ and about 20μ; and
a plurality of semiconductor microparticles having sizes in any dimension between about 1μ and about 20μ.

52. The composition of claim 49, wherein each nanoparticle of the plurality of metallic nanoparticles and of the plurality of semiconductor nanoparticles comprises an alloy of a metal and a semiconductor.

53. The composition of claim 49, wherein each semiconductor nanoparticle of the plurality of semiconductor nanoparticles further comprises a dopant selected from the group consisting of: boron, arsenic, phosphorus, gallium, and mixtures thereof.

54. The composition of claim 49, wherein the plurality of metallic nanoparticles comprises at least one metal selected from the group consisting of: aluminum, copper, silver, gold, nickel, palladium, tin, platinum, lead, zinc, bismuth, alloys thereof, and mixtures thereof.

55. The composition of claim 49, wherein the plurality of semiconductor nanoparticles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof.

56. The composition of claim 49, wherein at least some nanoparticles of the plurality of metallic nanoparticles are passivated with at least a partial coating selected from the group consisting of: benzotriazole, zinc phosphate, zinc dithiophosphate, tannic acid, hexafluoroacetylacetone, and mixtures thereof.

57. The composition of claim 49, further comprising:
an antioxidant selected from the group consisting of: N,N-diethylhydroxylamine, ascorbic acid, hydrazine, hexamine, phenylenediamine, and mixtures thereof.

58. The composition of claim 49, wherein:
the plurality of metallic nanoparticles are comprised of aluminum and are present in an amount of about 7% to 9% by weight;
the plurality of semiconductor nanoparticles are comprised of silicon and are present in an amount of about 27.5% to 32.5% by weight;
the first solvent is present in an amount of about 42% to 46% by weight and comprises glycerin; and
the second solvent is present in an amount of about 17% to 21% by weight and comprises glutaric acid.

59. A composition comprising:
a plurality of metallic particles;
a plurality of semiconductor particles, wherein the pluralities of metallic particles and semiconductor particles have sizes in any dimension between about 5 nm and about 20μ;
a first solvent comprising a polyol selected from the group consisting of: glycerin, diol, triol, tetraol, pentaol, ethylene glycols, diethylene glycols, polyethylene glycols, propylene glycols, dipropylene glycols, glycol ethers, glycol ether acetates 1,4-butanediol, 1,2-butanediol, 2,3-butanediol, 1,3-propanediol, 1,4-butanediol, 1,5-pentanediol, 1,8-octanediol, 1,2-propanediol, 1,3-butanediol, 1,2-pentanediol, etohexadiol, p-menthane-3,8-diol, 2-methyl-2,4-pentanediol, and mixtures thereof; and
a second solvent comprising a dicarboxylic acid selected from the group consisting of: ethanedioic (oxalic) acid; propanedioic (malonic) acid, butanedioic (succinic) acid, pentanedioic (glutaric) acid, hexanedioic (adipic) acid, heptanedioic (pimelic) acid, octanedioic (suberic) acid, nonanedioic (azelaic) acid, decanedioic (sebacic) acid, undecanedioic acid, dodecanedioic acid, tridecanedioic (brassylic) acid, tetradecanedioic acid, pentadecanedioic acid, hexadecanedioic (thapsic) acid, octadecanedioic acid, and mixtures thereof.

60. The composition of claim 59, wherein each particle of the plurality of metallic particles and of the plurality of semiconductor particles comprises an alloy of a metal and a semiconductor.

61. The composition of claim 59, wherein each semiconductor particle of the plurality of semiconductor particles further comprises a dopant selected from the group consisting of: boron, arsenic, phosphorus, gallium, and mixtures thereof.

62. The composition of claim 59, wherein the plurality of metallic particles comprises at least one metal selected from the group consisting of: aluminum, copper, silver, gold, nickel, palladium, tin, platinum, lead, zinc, bismuth, alloys thereof, and mixtures thereof.

63. The composition of claim 59, wherein the plurality of semiconductor particles comprises at least one semiconductor selected from the group consisting of: silicon, gallium arsenide (GaAs), gallium nitride (GaN), GaP, InAlGaP, InAlGaP, AlInGaAs, InGaNAs, AlInGaSb, and mixtures thereof.

64. The composition of claim 59, wherein at least some particles of the plurality of metallic particles are passivated with at least a partial coating selected from the group consisting of: benzotriazole, zinc phosphate, zinc dithiophosphate, tannic acid, hexafluoroacetylacetone, and mixtures thereof.

65. The composition of claim 59, further comprising:
an antioxidant selected from the group consisting of: N,N-diethylhydroxylamine, ascorbic acid, hydrazine, hexamine, phenylenediamine, and mixtures thereof

66. The composition of claim 59, wherein:
the plurality of metallic particles are comprised of aluminum and are present in an amount of about 7% to 9% by weight;
the plurality of semiconductor particles are comprised of silicon and are present in an amount of about 27.5% to 32.5% by weight;
the first solvent is present in an amount of about 42% to 46% by weight and comprises glycerin; and
the second solvent is present in an amount of about 17% to 21% by weight and comprises glutaric acid.

67. A composition comprising:
a plurality of metallic particles;
a plurality of semiconductor particles, wherein the pluralities of metallic particles and semiconductor particles have sizes in any dimension between about 5 nm and about 1.5μ;
a first solvent comprising glycerin; and
a second solvent comprising pentanedioic (glutaric) acid;
wherein the viscosity of the composition is substantially between about 50 cps to about 25,000 cps at 25° C.
